(19) United States
(12) Patent Application Publication
(10) Pub. No.: US 2024/0210608 A1
(43) Pub. Date: Jun. 27, 2024

(54) OPTICAL MEMBER AND DISPLAY APPARATUS COMPRISING THE SAME

(71) Applicant: LG Display Co., Ltd., Seoul (KR)

(72) Inventors: JuHun MIN, Paju-si (KR); SunWoong KIM, Paju-si (KR); SeungSoo YANG, Paju-si (KR); ChangHee CHOI, Paju-si (KR)

(21) Appl. No.: 18/454,256

(22) Filed: Aug. 23, 2023

(30) Foreign Application Priority Data
Dec. 26, 2022 (KR) 10-2022-0184728

(51) Int. Cl. G02B 5/30; H10K 59/80

(52) U.S. Cl. CPC G02B 5/3083; H10K 59/879; H10K 59/8791

(57) ABSTRACT

An optical member capable of reducing reflectance of external light and a display apparatus comprising the same are provided. The optical member comprises a first layer including a pattern portion having a plurality of concave portions and a plurality of convex portions between the plurality of concave portions, and a second layer covering the pattern portion. The first layer and the second layer have their respective refractive indexes different from each other, and a first phase of light passing through the plurality of convex portions is different from a second phase of light passing through the plurality of concave portions.

### CROSS-REFERENCE TO RELATED APPLICATIONS

This application claims the benefit of the Korean Patent Application No. 10-2022-0184728 filed on Dec. 26, 2022, which is hereby incorporated by reference as if fully set forth herein.

### BACKGROUND

### Technical Field

The present disclosure relates to an optical member for displaying an image and a display apparatus comprising the same.

### Description of the Related Art

Among display apparatuses, an organic light emitting display apparatus has a high response speed, low power consumption, and self-emits light without requiring a separate light source unlike a liquid crystal display apparatus, there is no problem in a viewing angle and thus the organic light emitting display apparatus has received attention as a next-generation flat panel display apparatus.

The organic light emitting display apparatus displays an image through light emission of a light emitting element layer that includes a light emitting layer interposed between two electrodes.

### BRIEF SUMMARY

The inventors have realized a problem that often light extraction efficiency of the organic light emitting display apparatus is reduced as some of light emitted from the light emitting element layer is not emitted to the outside due to total reflection on the interface between the light emitting element layer and an electrode and/or between a substrate and an air layer. Therefore, it is beneficial to increase light extraction efficiency of light trapped in the organic light emitting display apparatus. However, increasing light extraction efficiency is somewhat limited due to the increase of reflectance, which is caused by external light.

The present disclosure has been made in view of the various technical problems in the related art as well as the above problems identified by the inventors. Various embodiments of the present disclosure provide an optical member capable of reducing reflectance of external light and a display apparatus comprising the same.

Various embodiments of the present disclosure provide an optical member capable of improving light extraction efficiency of light emitted from a light emitting element layer and a display apparatus comprising the same.

Various embodiments of the present disclosure provide a display apparatus capable of reducing overall power consumption through light extraction.

Various embodiments of the present disclosure provide an optical member capable of minimizing and reducing occurrence of a radial rainbow pattern and a radial circular ring pattern based on a diffraction pattern of reflective light generated by destructive interference and/or constructive interference of light caused by reflection of external light, and a display apparatus comprising the same.

Various embodiments of the present disclosure provide an optical member capable of reducing degradation of black visibility characteristics, which is caused by reflection of external light, and a display apparatus comprising the same.

In addition to the technical benefits of the present disclosure as mentioned above, additional benefits and features of the present disclosure will be clearly understood by those skilled in the art from the following description of the present disclosure.

In accordance with an aspect of the present disclosure, the above and other benefits can be accomplished by the provision of an optical member comprising a first layer including a pattern portion having a plurality of concave portions and a plurality of convex portions between the plurality of concave portions, and a second layer covering the pattern portion, wherein the first layer and the second layer have their respective refractive indexes different from each other, and a first phase of light passing through the plurality of convex portions is different from a second phase of light passing through the plurality of concave portions.

In accordance with an aspect of the present disclosure, the above and other benefits can be accomplished by the provision of a display apparatus comprising a display panel displaying an image, and an optical panel coupled to the display panel, wherein the optical panel includes the optical member, and the optical member includes a first layer including a pattern portion having a plurality of concave portions and a plurality of convex portions between the plurality of concave portions, and a second layer covering the pattern portion, the first layer and the second layer have their respective refractive indexes different from each other, and a first phase of light passing through the plurality of convex portions is different from a second phase of light passing through the plurality of concave portions.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a schematic perspective view illustrating a display apparatus according to one embodiment of the present disclosure;

FIG. 2 is a schematic cross-sectional view taken along line I-I′ shown in FIG. 1. Illustrating an optical member of a display apparatus according to one embodiment of the present disclosure;

FIG. 3 is a schematic plan view illustrating a display panel included in a display apparatus according to one embodiment of the present disclosure;

FIG. 4 is a schematic cross-sectional view illustrating a display panel of a display apparatus according to one embodiment of the present disclosure, especially one subpixel;

FIG. 5 is a schematic view illustrating external light passing through an optical member of a display apparatus according to one embodiment of the present disclosure;

FIG. 6A is a view illustrating an external light image before passing through an optical member according to one embodiment of the present disclosure;

FIG. 6B is a view illustrating an external light image after passing through the optical member according to one embodiment of the present disclosure;

FIGS. 7A and 7B are comparison examples illustrating surface luminance of a display apparatus having no optical member;

FIGS. 8A and 8B are views illustrating surface luminance of a display apparatus according to one embodiment of the present disclosure;

FIGS. 9A to 9C are images illustrating diffraction scattering dispersion patterns for each of the display apparatus according to one embodiment of the present disclosure and a display apparatus of a comparative example by intensity of external light;

FIG. 10 is a graph illustrating that a color viewing angle of a display apparatus according to one embodiment of the present disclosure is compared with a color viewing angle of a display apparatus of a comparative example;

FIG. 11 is a graph illustrating that a luminance viewing angle of the display apparatus according to one embodiment of the present disclosure is compared with a luminance viewing angle of a display apparatus of a comparative example;

FIGS. 12A and 12B are views illustrating various shapes of a pattern portion included in an optical member of a display apparatus according to one embodiment of the present disclosure;

FIG. 13A is a view illustrating a display apparatus according to the first embodiment of the present disclosure;

FIG. 13B is a view illustrating a modified example of a display apparatus according to the first embodiment of the present disclosure;

FIG. 14 is a view illustrating a display apparatus according to the second embodiment of the present disclosure;

FIG. 15 is a view illustrating a display apparatus according to the third embodiment of the present disclosure;

FIG. 16 is a view illustrating a display apparatus according to the fourth embodiment of the present disclosure; and

FIG. 17 is a view illustrating a display apparatus according to the fifth embodiment of the present disclosure.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings. The present disclosure may, however, be embodied in different forms and should not be construed as limited to the embodiments set forth herein.

Rather, these embodiments are provided so that this disclosure will be thorough and complete, and will fully convey the scope of the present disclosure to those skilled in the art.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted.

In a case where ‘comprise,’ ‘have,’ and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when a position relation between two parts is described as ‘on˜,’ ‘over˜,’ ‘under˜,’ and ‘next˜,’ one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction,” “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand.

The embodiments of the present disclosure may be carried out independently from each other or may be carried out together in co-dependent relationship.

Hereinafter, the preferred embodiments of the present disclosure will be described in detail with reference to the accompanying drawings.

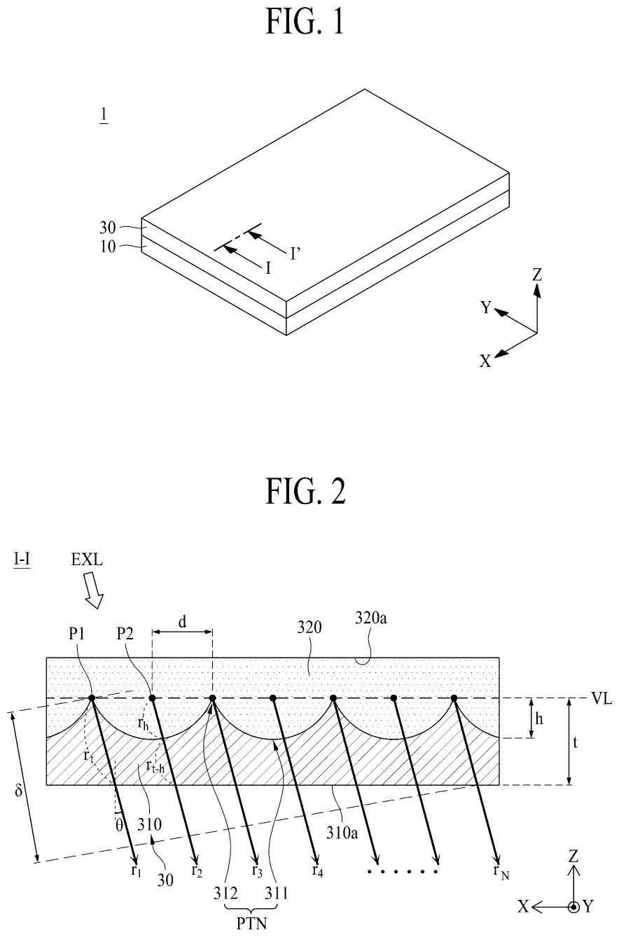

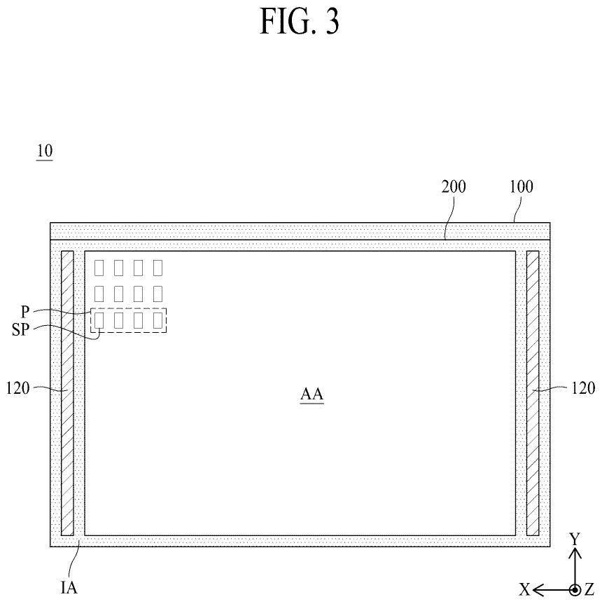

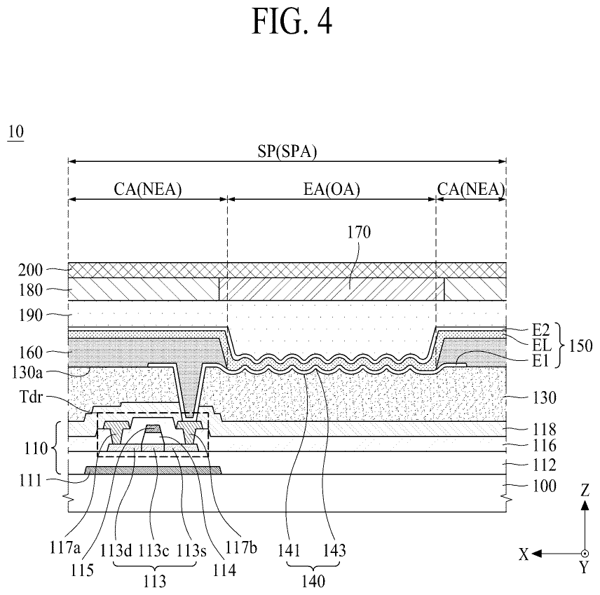

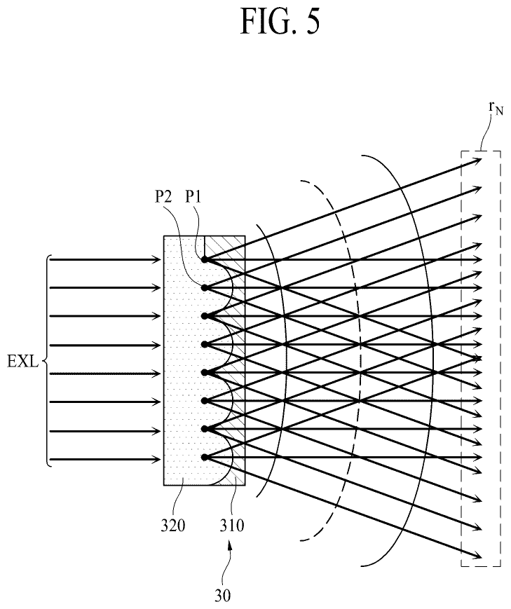

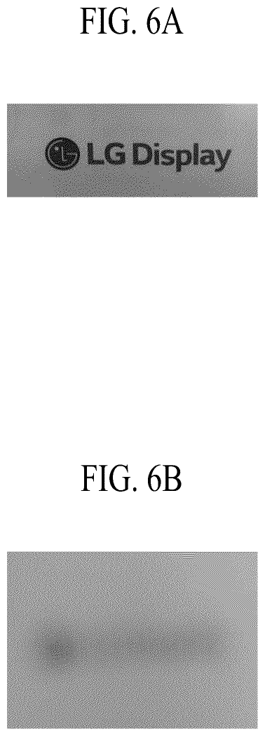

FIG. 1 is a schematic perspective view illustrating a display apparatus according to one embodiment of the present disclosure, FIG. 2 is a schematic cross-sectional view taken along line I-I′ shown in FIG. 1. Illustrating an optical member of a display apparatus according to one embodiment of the present disclosure, FIG. 3 is a schematic plan view illustrating a display panel included in a display apparatus according to one embodiment of the present disclosure, FIG. 4 is a schematic cross-sectional view illustrating a display panel of a display apparatus according to one embodiment of the present disclosure, especially one subpixel, and FIG. 5 is a schematic view illustrating external light passing through an optical member of a display apparatus according to one embodiment of the present disclosure.

Referring to FIGS. 1 to 4, an optical member 30 according to one embodiment of the present disclosure may include a first layer 310 including a pattern portion PTN having a plurality of concave portions 311 and a plurality of convex portions 312, and a second layer 320 covering the pattern portion PTN. The first layer 310 and the second layer 320 may have different refractive indexes. Therefore, a first phase of light passing through the plurality of convex portions 312 may be different from a second phase of light passing through the plurality of concave portions 311. Therefore, the optical member 30 according to one embodiment of the present disclosure may convert light (or external light) incident from the outside into diffractive light.

When the incident external light is converted into diffractive light, the diffractive light is bent and spread to an area which cannot be reached by a refraction phenomenon which is a main characteristic of the diffractive light, whereby spatial luminance distribution of the external light incident on the light extraction portion 140 (shown in FIG. 4) of the display panel 10, which will be described later, may be subdivided. The intensity of the light may be weakened through constructive interference and/or destructive interference by the lights of the subdivided phase, and a spectral dispersion pattern may be controlled to a brightness level that is not visible to the eye as the light of which intensity is weakened is incident on the light extraction portion 140.

As a result, the optical member 30 according to one embodiment of the present disclosure includes a first layer 310 and a second layer 320, which have different refractive indexes, and the first layer 310 includes a pattern portion PTN having a plurality of concave portions 311 and a plurality of convex portions 312, whereby incident external light may be converted into diffractive light to weaken the intensity of emitted light. Therefore, the optical member 30 according to one embodiment of the present disclosure may have a polarization function for shielding external light reflected by the light extraction portion 140 and the pixel circuit.

The display apparatus 1 according to one embodiment of the present disclosure may include a display panel 10 for displaying an image and an optical panel LP coupled to the display panel 10. The optical panel LP may include the optical member 30.

Therefore, in the display apparatus 1 according to one embodiment of the present disclosure, since the intensity of external light incident through the optical member 30 may be reduced (or the diffraction pattern of the reflective light may be suppressed or minimized), occurrence of a radial rainbow pattern and a radial circular ring pattern based on the diffraction pattern of the reflective light generated by destructive interference and/or constructive interference of light caused by reflection of external light may be minimized or reduced.

Also, in the display apparatus 1 according to one embodiment of the present disclosure, since external light may be subdivided by the optical member 30, occurrence of the radial rainbow pattern and the radial circular ring pattern due to external light may be suppressed or minimized, whereby real black visibility in a non-driving or off state may be implemented.

Hereinafter, the optical member 30 according to one embodiment of the present disclosure will be described in more detail with reference to FIGS. 1 to 5.

Referring to FIG. 2, the optical member 30 according to one embodiment may include a lens-shaped pattern portion PTN. The pattern portion PTN may include a plurality of concave portions 311 and a plurality of convex portions 312. As shown in FIG. 2, the plurality of concave portions 311 and the plurality of convex portions 312 may be formed in the first layer 310. The second layer 320 may be formed to cover the pattern portion PTN. The second layer 320 according to one embodiment may have a refractive index different from that of the first layer 310.

As shown in FIG. 2, the first layer 310 of the optical member 30 may include a plurality of first points P1. The second layer 320 of the optical member 30 may include a plurality of second points P2. The plurality of second points P2 may also be referred to as a plurality of middle points P2 (or center points P2) as it is in the middle of adjacent first points P1. Therefore, a phase of the external light passing through each of the first points P1 may be converted by the influence of the refractive index of the first layer 310. In addition, a phase of the external light passing through each of the second points P2 may be converted by the influence of the refractive index of the second layer 320 and the refractive index of the first layer 310. Therefore, a first phase of light passing through the plurality of first points P1 may be different from a second phase of light passing through the plurality of second points P2.

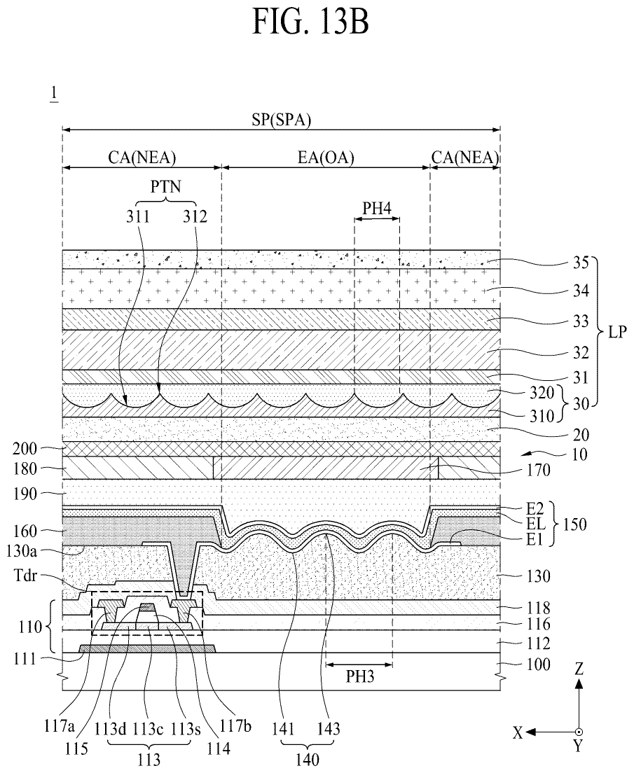

The plurality of first points P1 according to one embodiment may be disposed on the uppermost side of each of the plurality of convex portions 312. The plurality of convex portions 312 may be formed by a photo process and a patterning process (or ashing process) on the first layer 310 having the same thickness. As shown in FIG. 2, the plurality of first points P1 may refer to points on the uppermost side of the plurality of convex portions 312. The plurality of first points P1 may also be referred to as the high points P1 as it is at the high point of the first layer 310 in the Z direction. The distance between adjacent high points P1 may be referred to as a pitch (see PH2 in FIG. 13A and PH4 in FIG. 13B). The first layer 310 may have various selected curvature between adjacent high points P1 and this pattern may be repeated in the optical panel. The plurality of first points P1 may be represented by points spaced farthest from a rear surface 310a of the first layer 310 in each of the plurality of convex portions 312. Therefore, the plurality of first points P1 may be points on the upper surface of the first layer 310 constituting a maximum thickness ‘t’ of the first layer 310. The maximum thickness ‘t’ of the first layer 310 may be expressed as a height of the convex portion 312. The first layer 310 includes a pattern or a pattern portion. The shape of the pattern can be a wave pattern, a zigzag pattern, a jagged pattern, a triangular wave pattern, or any other suitable pattern for achieving the technical benefits discussed herein. The pattern in the first layer 310 includes an upper surface or a top surface that abuts the second layer 320 that is on the first layer 310. The top surface between adjacent high points P1 may have various selected curvature for achieving the technical benefits discussed herein.

The second point P2 according to one example may be disposed between the plurality of first points P1. Therefore, as shown in FIG. 2, the plurality of second points P2 may be disposed on the plurality of concave portions 311. That is, the plurality of second points P2 may be disposed on the upper surface of the first layer 310 constituting each of the plurality of concave portions 311. The plurality of concave portions 311 may be simultaneously formed through the same process as that of the plurality of convex portions 312. The plurality of second points P2 may be points vertically above the upper surface of the first layer 310 constituting a maximum depth ‘h’ of each of the plurality of concave portions 311. That is, the second points P2 may be in the center of two adjacent high points P1.

As shown in FIG. 2, the plurality of first points P1 may be disposed at the same height as the plurality of second points P2 based on the rear surface 310a of the first layer 310. Therefore, the first points P1 and the second points P2 may be disposed in a row on a virtual line VL disposed in parallel with the rear surface 310a of the first layer 310.

Each of the plurality of second points P2 may be disposed at the center between the plurality of first points P1. For example, as shown in FIG. 2, each of the plurality of second points P2 may be disposed at a position spaced apart from one first point P1 at a first distance ‘d.’ The first distance ‘d’ may be a horizontal distance between the highest height of the first layer 310 and the lowest height of the first layer 310. Therefore, the first points P1 and the second points P2 may be disposed at the first distance ‘d’ along a first direction (X-axis direction). As a result, the first points P1 and the second points P2 may be disposed at constant intervals along the first direction (X-axis direction). The first direction (X-axis direction) may be a horizontal direction (or long side direction) of the display apparatus 1 based on FIG. 1. The second direction (Y-axis direction) is perpendicular to the first direction (X-axis direction), and may be a vertical direction (or short side direction) of the display apparatus 1 based on FIG. 1. A third direction (Z-axis direction) is a direction perpendicular to each of the first direction (X-axis direction) and the second direction (Y-axis direction), and may be a thickness direction of the display apparatus 1 based on FIG. 1.

Each of the plurality of first points P1 and the plurality of second points P2 may function as a diffraction slit for diffracting light. Therefore, the plurality of first points P1 and the plurality of second points P2 may have the same function as that of a multi-diffraction slit for transmitting light, and thus, the external light passing through the first points P1 and the second points P2 may be converted into diffractive light. As external light is converted into diffractive light, the light may be subdivided and the intensity of light may be reduced through constructive interference and/or destructive interference. That is, the light of the first phase and the light of the second phase, which have passed through the first layer 310 and the second layer 320, may be subjected to constructive interference and/or destructive interference so that the intensity of light may be reduced.

Meanwhile, as shown in FIG. 2, since the positions at which the plurality of first points P1 and the plurality of second points P2 are disposed are different from each other, the first phase of light passing through the plurality of first points P1 may be different from the second phase of light passing through the plurality of second points P2. As the first phase of light passing through the first points P1 and the second phase of light passing through the second points P2 are different from each other, constructive interference and/or destructive interference may be more generated in comparison with lights having the same phase. Therefore, since the optical member 30 according to one embodiment of the present disclosure may convert incident external light into diffractive light, the intensity of emitted light may be reduced. This will be further described with reference to FIG. 5.

Referring back to FIG. 2, an upper surface 320a of the second layer 320 may be formed to be flat. Therefore, the optical member 30 according to one embodiment of the present disclosure may be easily coupled to the display panel through an adhesive such as OCA, PSA, or the like. Similarly, as the lower surface 310a of the first layer 310 is formed to be flat, the optical member 30 according to one embodiment of the present disclosure may be easily coupled to the display panel through an adhesive such as OCA, PSA, or the like. That is, in the optical member 30 according to one embodiment of the present disclosure, at least one surface of each of the first layer 310 and/or the second layer 320 is provided as a flat surface without bending of the pattern portion PTN, so that the optical member 30 may be easily integrated with other optical components such as a polarizing plate.

The optical member 30 may be included in the optical panel LP (shown in FIG. 13) together with at least one of a phase delay layer, a protective layer, a polarization conversion layer, or an anti-reflective film.

Hereinafter, the display apparatus 1 according to one embodiment of the present disclosure will be described below with reference to FIGS. 3 and 4.

Referring to FIG. 3, the display apparatus 1 according to one embodiment of the present disclosure may include a display panel 10 and an optical panel LP coupled to the display panel 10. The optical panel LP may include the optical member 30 described above. Therefore, the optical panel LP may reduce the intensity of external light incident on the display panel 10 by converting external light incident on the display panel 10 into diffractive light.

The display panel 10 may include a substrate 100 and an opposite substrate 200, which are bonded to each other.

The substrate 100 may include a first substrate, a lower substrate, a transparent glass substrate or a transparent plastic substrate. The substrate 100 may include a display area AA and a non-display area IA.

The display area AA is an area where an image is displayed, and may be a pixel array area, an active area, a pixel array unit, a display unit, or a screen. For example, the display area AA may be disposed at a central portion of the display panel 10. The display area AA may include a plurality of pixels P.

A plurality of pixels P may be defined as unit areas in which light is actually emitted. Each of the plurality of pixels P may include a plurality of subpixels SP. According to one embodiment, each of the plurality of pixels P may include at least one red subpixel, at least one green subpixel, at least one blue subpixel, and at least one white subpixel, but is not limited thereto. For example, each of the plurality of pixels P may include a red subpixel, a green subpixel, a blue subpixel, and a white subpixel. Sizes of the plurality of subpixels included in each of the plurality of pixels P may be the same as or different from each other.

The non-display area IA is an area on which an image is not displayed, and may be a peripheral area, a signal supply area, an inactive area or a bezel area. The non-display area IA may be configured to be in the vicinity of the display area AA. The display panel 10 or the substrate 100 may further include a peripheral circuit portion 120 disposed in a non-display area IA.

The peripheral circuit portion 120 may include a gate driving circuit connected to the plurality of pixels P. The gate driving circuit may be integrated in the non-display area IA at one side or both sides of the substrate 100 in accordance with a manufacturing process of the thin film transistor, and may be connected to the plurality of pixels P. For example, the gate driving circuit may include a known shift register.

The opposite substrate 200 may encapsulate (or seal) the display area AA disposed on the substrate 100. For example, the opposite substrate 200 may be bonded to the substrate 100 via an adhesive member (or clear glue). The opposite substrate 200 may be an upper substrate, a second substrate, or an encapsulation substrate.

The optical panel LP may be coupled to the display panel 10 of the display apparatus 1 according to one embodiment of the present disclosure to reduce the intensity of external light incident on the display panel 10. The optical panel LP according to one example may be coupled to an upper side of the display panel 10 or a lower side of the display panel 10. The optical panel LP (or the optical member 30) according to another example may be formed (or coupled) inside the display panel 10. The optical panel LP will be described in detail with reference to FIG. 13.

FIG. 4 is a cross-sectional view illustrating one subpixel shown in FIG. 3.

Referring to FIGS. 3 and 4, the display panel 10 according to one embodiment of the present disclosure may include a plurality of subpixels SP.

Each of the plurality of subpixels SP may be disposed in each of a plurality of subpixel areas SPA disposed in the pixel P (or pixel area). The subpixel area SPA according to one embodiment may include a circuit area CA and a light emission area EA. The circuit area CA may be spatially separated from the light emission area EA in the subpixel area SPA, but is not limited thereto. For example, at least a portion of the circuit area CA may overlap the light emission area EA in the subpixel area SPA or may be disposed below the light emission area EA. The light emission area EA may be an opening area OA, a light emitting area, a transmissive area, or a transmissive portion. For example, the circuit area CA may be a non-light emission area NEA or a non-opening area. The subpixel area SPA according to another embodiment may further include a transparent portion disposed near at least one of the light emission area EA or the circuit area CA. For example, one pixel may include a light emission area for each pixel corresponding to each of the plurality of subpixels SP and a transparent portion disposed near each of the plurality of subpixels SP. In this case, the light emitting display apparatus may realize a transparent light emitting display apparatus due to light transmission of the transparent portion.

The display panel 10 according to one embodiment of the present disclosure may include a pixel circuit layer 110, an overcoat layer 130 and a light emitting element layer 150, which are disposed on the substrate 100.

The pixel circuit layer 110 may include a buffer layer 112, a pixel circuit, and a passivation layer 118.

The buffer layer 112 may be disposed on an entire first surface (or upper surface) of the substrate 100. The buffer layer 112 may serve to prevent materials contained in the substrate 100 from being diffused into a transistor layer or prevent external water or moisture from being permeated into the light emitting element layer 150 during a high temperature process of a manufacturing process of the thin film transistor. For example, the buffer layer 112 may be a first insulating layer, a first inorganic material layer or a lowermost insulating layer among a plurality of insulating layers disposed on the pixel circuit layer of the substrate 100.

The pixel circuit may include a driving thin film transistor Tdr disposed in the circuit area CA of each subpixel SP (or subpixel area SPA). The driving thin film transistor Tdr may include an active layer 113, a gate insulating layer 114, a gate electrode 115, an interlayer insulating layer 116, a drain electrode 117a, and a source electrode 117b.

The active layer 113 may be formed of a semiconductor material based on any one of amorphous silicon, polycrystalline silicon, oxide and organic material.

The gate insulating layer 114 may be formed on the channel area of the active layer 113. As an example, the gate insulating layer 114 may be formed in an island shape only on the channel area of the active layer 113, or may be formed on an entire front surface of the substrate 100 or the buffer layer 112, which includes the active layer 113. For example, when the gate insulating layer 114 is formed on the entire surface of the buffer layer 112, the gate insulating layer 114 may be a second insulating layer, a second inorganic material layer or a lowermost intermediate insulating layer among a plurality of insulating layers disposed on the pixel circuit layer of the substrate 100.

The gate electrode 115 may be disposed on the gate insulating layer 114 to overlap a channel area 113c of the active layer 113.

The interlayer insulating layer 116 may be formed on the gate electrode 115 and the drain area 113d and the source area 113s of the active layer 113. The interlayer insulating layer 116 may be formed on the substrate 100 or an entire surface of the buffer layer 112. For example, the interlayer insulating layer 116 may be a third insulating layer, a third inorganic material layer, or an upper insulating layer among a plurality of insulating layers disposed on the substrate 100.

The drain electrode 117a may be disposed on the interlayer insulating layer 116 so as to be electrically connected to a drain area 113d of the active layer 113. The source electrode 117b may be disposed on the interlayer insulating layer 116 so as to be electrically connected to a source area 113s of the active layer 113.

The pixel circuit may further include first and second switching thin film transistors and at least one capacitor, which are disposed in the circuit area CA together with the driving thin film transistor Tdr. The display panel according to the present disclosure may further include a light shielding layer 111 provided below the active layer 113 of at least one of the driving thin film transistor Tdr, the first switching thin film transistor or the second switching thin film transistor. The light shielding layer 111 may be configured to minimize or prevent a change in a threshold voltage of the thin film transistor due to external light.

The passivation layer 118 may be disposed over the substrate 100 to cover the pixel circuit. For example, the passivation layer 118 may be configured to cover the drain electrode 117a, the source electrode 117b, and the interlayer insulating layer 116 of the driving thin film transistor Tdr. For example, the passivation layer 118 may be made of an inorganic insulating material. For example, the passivation layer 118 may be a fourth insulating layer, a fourth inorganic material layer or an uppermost intermediate insulating layer among a plurality of insulating layers disposed on the pixel circuit layer of the substrate 100.

The overcoat layer 130 may be provided on the substrate 100 to cover the pixel circuit layer 110. The overcoat layer 130 may be formed in the other area except a pad area of the non-display area and the entire display area. For example, the overcoat layer 130 may include an extension portion (or an enlarged portion) extended or enlarged from the display area to the other non-display area except the pad area. Therefore, the overcoat layer 130 may have a size relatively wider than that of the display area.

The overcoat layer 130 according to one example may be formed to have a relatively thick thickness, thereby providing a flat surface on the pixel circuit layer 110. For example, the overcoat layer 113 may be made of an organic material such as photo acryl, benzocyclobutene, polyimide and fluorine resin. For example, the overcoat layer 130 may be a fifth insulating layer, an organic material layer, an uppermost insulating layer or a planarization layer among a plurality of insulating layers disposed on the substrate 100.

The overcoat layer 130 may include a light extraction portion 140 disposed in each subpixel SP. The light extraction portion 140 may be formed on an upper surface 130a of the overcoat layer 130 to overlap the light emission area EA of the subpixel area SPA. Therefore, the light extraction portion 140 may overlap at least one of the plurality of concave portions 311 or the plurality of convex portions 312, which are included in the optical member 30.

The light extraction portion 140 may be formed on the overcoat layer 130 of the light emission area EA to have a curved (or uneven) shape, thereby changing a propagation path of light emitted from the light emitting element layer 150 to increase light extraction efficiency. For example, the light extraction portion 140 may be a non-flat portion, an uneven pattern portion, a micro lens portion, or a light scattering pattern portion.

The light extraction portion 140 may include a plurality of concave patterns 141 and a convex pattern 143 disposed near each of the plurality of concave patterns 141. The plurality of concave patterns 141 may be concavely formed or configured from the upper surface 130a of the overcoat layer 130. The convex pattern 143 may be disposed between the plurality of concave patterns 141. The convex pattern 143 may be formed to surround each of the plurality of concave patterns 141.

An upper portion of the convex pattern 143 may have a convex curved shape to increase light extraction efficiency, but is not limited thereto. For example, the upper portion of the convex pattern 143 may include a pointed tip structure. For example, the upper portion of the convex pattern 143 may include a convex cross-sectional dome or bell structure, but is not limited thereto.

The convex pattern 143 may include an inclined portion having a curved shape between a bottom portion and an upper portion (or a top portion). The inclined portion of the convex pattern 143 may form or configure the concave pattern 141. For example, the inclined portion of the convex pattern 143 may be an inclined surface or a curved portion. The inclined portion of the convex pattern 143 according to one embodiment may have a cross-sectional structure of a Gaussian curve. In this case, the inclined portion of the convex pattern 143 may have a tangent slope that is gradually increased from the bottom portion to the upper portion and gradually reduced.

The light emitting element layer 150 may be disposed on the light extraction portion 140 that overlaps the light emission area EA. The light emitting element layer 150 may be configured to emit light toward an opposing substrate 200 in accordance with a top emission type, but the embodiment of the present disclosure is not limited thereto. The light emitting element 150 according to one embodiment may include a first electrode E1, a light emitting layer EL and a second electrode E2.

The first electrode E1 may be formed on the overcoat layer 130 of the subpixel area SPA and electrically connected to the source electrode 117b (or the drain electrode 117a) of the driving thin film transistor Tdr. One end of the first electrode E1 adjacent to the circuit area CA may be electrically connected to the source electrode 117b (or the drain electrode 117a) of the driving thin film transistor Tdr through an electrode contact hole provided in the overcoat layer 130 and the passivation layer 118.

Since the first electrode E1 is directly in contact with the light extraction portion 140, the first electrode E1 has a shape that follows a shape of the light extraction portion 140. Since the first electrode E1 is formed (or deposited) on the overcoat layer 130 to have a relatively thin thickness, the first electrode E1 has a surface shape that conforms to a surface morphology of the light extraction portion 140 that includes the convex pattern 143 and the plurality of concave portions 141. For example, the first electrode E1 may have the same cross-sectional structure as that of the light extraction portion 140 as the first electrode E1 is formed in a conformal shape, which follows the surface shape (or morphology) of the light extraction portion 140, by a deposition process of a transparent conductive material.

The light emitting layer EL may be formed on the first electrode E1 and thus may be directly in contact with the first electrode E1. The light emitting layer EL may be formed (or deposited) on the first electrode E1 so as to have a relatively thick thickness as compared with the first electrode E1, thereby having a surface shape different from that of each of the plurality of concave portions 141 and the convex pattern 143 or that of the first electrode E1. For example, the light emitting layer EL may be formed in a non-conformal shape, which does not follow the surface shape (or morphology) of the first electrode E1, by a deposition process and thus may have a cross-sectional structure different from that of the first electrode E1.

The light emitting layer EL according to one embodiment may have a thickness that is gradually increased toward the bottom surface of the concave pattern 141. For example, the light emitting layer EL may be formed on the top of the convex pattern 143 to have a first thickness, may be formed on the bottom surface of the concave pattern 141 to have a second thickness thicker than the first thickness, and may be formed on the inclined surface (or the curved portion) of the convex pattern 143 to have a third thickness thinner than the first thickness. Each of the first to third thicknesses may correspond to a shortest distance between the first electrode E1 and the second electrode E2.

The light emitting layer EL according to one embodiment may include two or more organic light emitting layers for emitting white light. For example, the light emitting layer EL may include first and second organic light emitting layers for emitting white light by mixing first light with second light. For example, the first light emitting layer may include any one of a blue organic light emitting layer, a green organic light emitting layer, a red organic light emitting layer, a yellow organic light emitting layer and a yellow-green organic light emitting layer to emit the first light. For example, the second organic light emitting layer may include an organic light emitting layer for emitting the second light for implementing white light by mixture with the first light of the blue organic light emitting layer, the green organic light emitting layer, the red organic light emitting layer, the yellow organic light emitting layer and the yellow-green organic light emitting layer. The light emitting layer EL according to another embodiment may include any one of the blue organic light emitting layer, the green organic light emitting layer and the red organic light emitting layer. Additionally, the light emitting layer EL may include a charge generation layer interposed between the first organic light emitting layer and the second organic light emitting layer.

The second electrode E2 may be formed on the light emitting layer EL and thus may be directly in contact with the light emitting layer EL. The second electrode E2 may be formed (or deposited) on the light emitting layer EL to have a relatively thin thickness as compared with the light emitting layer EL. The second electrode E2 may be formed (or deposited) on the light emitting layer EL to have a relatively thin thickness, thereby having a surface shape that conforms to that of the light emitting layer EL. For example, the second electrode E2 may be formed in a conformal shape that conforms to the surface shape (or morphology) of the light emitting layer EL by a deposition process to have a cross-sectional structure the same as that of the light emitting layer EL and different from that of the light extraction portion 140.

The second electrode E2 according to one embodiment may include a metal material having low reflectance or a transflective metal to emit incident light, which is emitted from the light emitting layer EL, toward the opposing substrate 200, but is not limited thereto. When the display panel 10 of the present disclosure is implemented in a bottom emission type, the second electrode E2 may include a metal material having high reflectance to reflect light toward the substrate 100. For example, the second electrode E2 may include a single layered structure or multi-layered structure made of any one material selected from aluminum (Al), silver (Ag), molybdenum (Mo), gold (Au), magnesium (Mg), calcium (Ca) and barium (Ba), or two or more alloy materials. When the display panel 10 of the present specification is implemented in a bottom emission type, the second electrode E2 may include an opaque conductive material having high reflectivity. For example, the second electrode E2 may be a reflective electrode, a cathode electrode, a light-reflective surface, or a light-reflector, and in this case, the first electrode E1 may be an anode electrode or a transparent electrode.

The light emitting element layer 150 may emit light by a current supplied by the pixel circuit. The concave pattern 141 or the convex pattern 143 of the light extraction portion 140 increases external extraction efficiency of the light emitted from the light emitting layer EL by changing a path of the light emitted from the light emitting layer EL to the opposing substrate 200.

For example, the convex pattern 143 prevents or minimizes degradation of light extraction efficiency due to light trapped in the light emitting element layer 150 by repeating total reflection between the first electrode E1 and the second electrode E2 of the light emitting element layer 150 without moving the light emitted from the light emitting element layer 150 to the opposing substrate 200. Therefore, the display apparatus 1 according to one embodiment of the present disclosure may improve light extraction efficiency of the light emitted from the light emitting element layer 150.

In the display apparatus 1 according to one embodiment of the present disclosure, since light extraction efficiency may be improved through the light extraction portion 140, the display apparatus 1 may have the same light emission efficiency or higher light emission efficiency even with low power as compared with the display apparatus having no light extraction portion, whereby overall power consumption may be reduced.

The display panel 10 according to one embodiment of the present disclosure may further include a bank layer 160. The bank layer 160 may be provided on an edge of the first electrode E1 and the overcoat layer 130. The bank layer 160 may be formed of an organic material such as a benzocyclobutene (BCB)-based resin, an acryl-based resin or a polyimide resin.

The bank layer 160 may be provided on the upper surface 130a of the overcoat layer 130 to cover the edge of the first electrode E1 extended onto the circuit area CA. The light emission area EA defined by the bank layer 160 may have a size smaller than that of the light extraction portion 140 of the overcoat layer 130 in a plan view.

The light emitting layer EL of the light emitting element layer 150 may be formed on the first electrode E1, the bank layer 160, and a step difference portion between the first electrode E1 and the bank layer 160. In this case, when the light emitting layer EL is formed in the step difference portion between the first electrode E1 and the bank layer 160 to have a relatively thin thickness, the second electrode E2 may be in electrical contact (or short) with the first electrode E1. To solve this problem, an end (or outermost bank line) of the bank layer 160 adjacent to the light emission area EA may be disposed to cover an edge portion of the light extraction portion 140. Therefore, an electrical contact (or short) between the first electrode E1 and the second electrode E2 may be prevented from occurring due to an end of the bank layer 160 disposed in the step difference portion between the first electrode E1 and the bank layer 160.

The display panel 10 according to the present disclosure may further include a color filter layer 170.

The color filter layer 170 is for color conversion of light emitted from the light emitting element layer 150. When the display apparatus of the present disclosure is implemented in a top emission type, the color filter layer 170 according to one embodiment may be disposed between the opposing substrate 200 and the light emitting element layer 150 to overlap at least one light emission area EA. When the display apparatus of the present disclosure is implemented in a bottom emission type, the color filter layer 170 according to another embodiment may be disposed between the passivation layer 118 and the overcoat layer 130 to overlap the light emission area EA. The color filter layer 170 according to another embodiment may be disposed between the interlayer insulating layer 116 and the passivation layer 118 or between the substrate 100 and the interlayer insulating layer 116 to overlap the light emission area EA.

When the display panel 10 according to the present disclosure is coupled to the optical member 30, the color filter layer 170 may be disposed between the light emitting element layer 150 and the optical member 30. Therefore, the color filter layer 170 may color-convert light emitted from the light emitting element layer 150 and directed toward the optical member 30.

The color filter layer 170 may have a size larger than that of the light emission area EA. For example, the color filter layer 170 may have a size larger than that of the light emission area EA and smaller than that of the light extraction portion 140 of the overcoat layer 130, but is not limited thereto. The color filter layer 170 may have a size larger than that of the light extraction portion 140. For example, when the color filter layer 170 has a size larger than that of the light extraction portion 140, light leakage, in which internal light moves toward the subpixel SP adjacent thereto, may be reduced or minimized.

The color filter layer 170 according to one embodiment may include a color filter that transmits only a wavelength of a color, which is set in the subpixel SP among light emitted (or extracted) from the light emitting element 150 to the opposing substrate 200. For example, the color filter layer 170 may transmit a red, green or blue wavelength. When one pixel P includes first to fourth subpixels SP adjacent to one another, a color filter layer provided in the first subpixel may include a red color filter, a color filter layer provided in the second subpixel may include a green color filter, and a color filter layer provided in the third subpixel may include a blue color filter. The fourth subpixel may not include a color filter layer, or may include a transparent material for compensation of a step difference, thereby emitting white light.

The display panel 10 according to one embodiment of the present disclosure may include a black matrix 180.

The black matrix 180 may be formed in the non-emission area NEA adjacent to the light emission area EA. The black matrix 180 according to one example may be formed on the bank layer 160 to be adjacent to the color filter layer 170. For example, the black matrix 180 may surround the light emission area EA. The black matrix 180 may prevent light emitted from the subpixel SP for emitting light from being emitted toward an adjacent subpixel SP. Therefore, color mixture may be prevented from occurring between the subpixel SP for emitting light and the adjacent subpixel SP.

The display panel 10 according to one embodiment of the present disclosure may include an encapsulation portion 190.

The encapsulation portion 190 may be formed on the substrate 100 to cover the light emitting element layer 150. The encapsulation portion 190 may be provided on the substrate 100 to cover the second electrode E2. For example, the encapsulation portion 190 may surround the display area. The encapsulation portion 190 may serve to protect the thin film transistor and the light emitting layer EL from external impact and prevent oxygen and/or moisture or particles from being permeated into the light emitting layer EL.

The encapsulation portion 190 according to one embodiment may include a plurality of inorganic encapsulation layers. The encapsulation portion 190 may further include at least one organic encapsulation layer interposed between the plurality of inorganic encapsulation layers. The organic encapsulation layer may be expressed as a particle cover layer.

The encapsulation portion 190 according to another embodiment may be changed to a filler fully surrounding the display area, and in this case, the opposing substrate 200 may be bonded to the substrate 100 via the filler. The filler may include a getter material that absorbs oxygen and/or moisture.

The opposing substrate 200 may be coupled to the encapsulation portion 190. The opposing substrate 200 may be made of a plastic material, a glass material or a metal material. For example, when the encapsulation portion 190 includes a plurality of inorganic encapsulation layers, the opposing substrate 200 may be omitted.

Optionally, when the encapsulation portion 190 is changed to the filler, the opposing substrate 200 may be coupled to the filler, and in this case, the opposing substrate 200 may be made of a plastic material, a glass material or a metal material.

Hereinafter, the optical member 30 according to one embodiment of the present disclosure will be described in detail with reference to FIGS. 2 and 5 to 11.

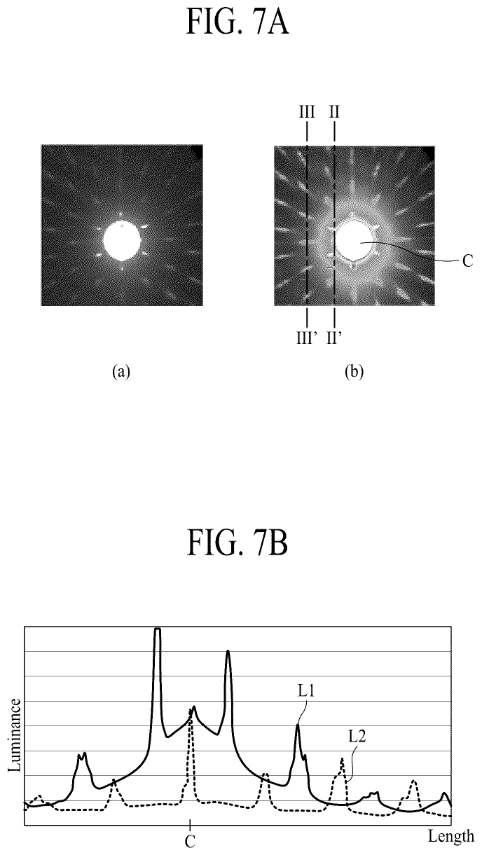

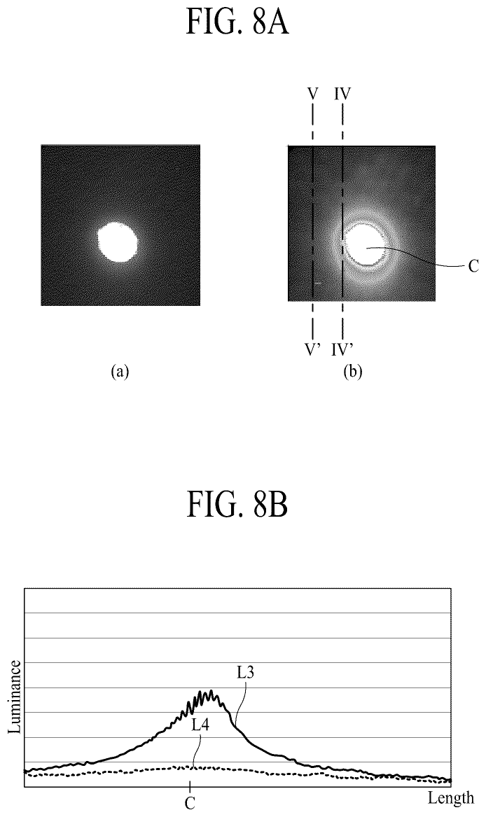

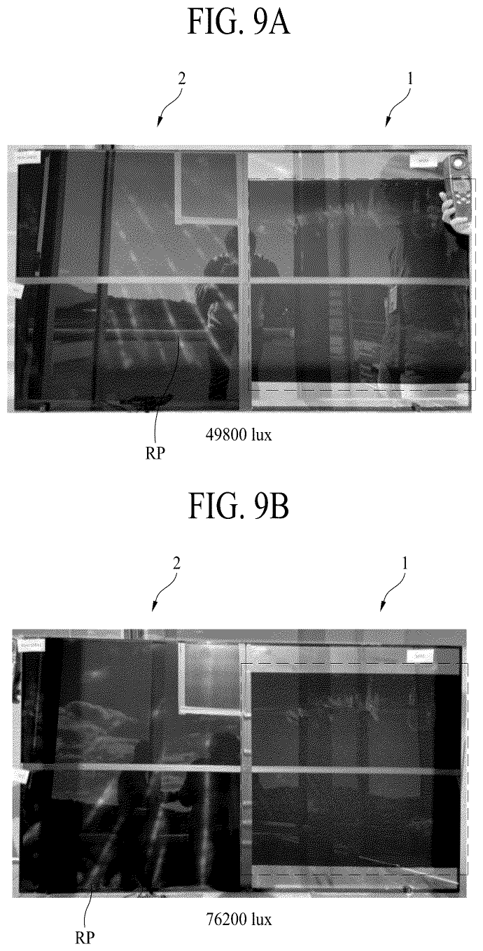

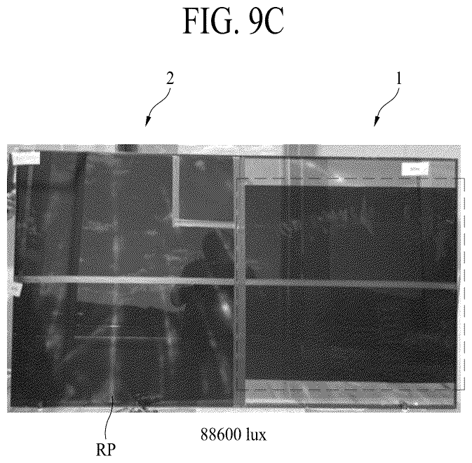

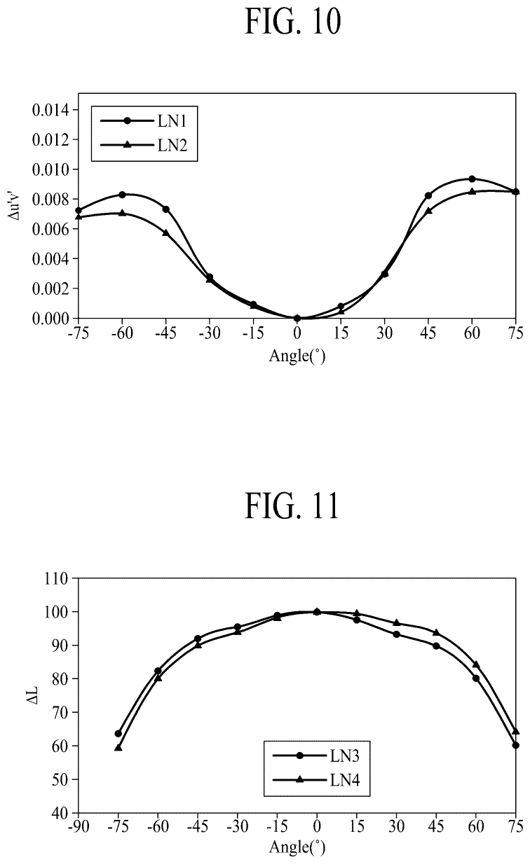

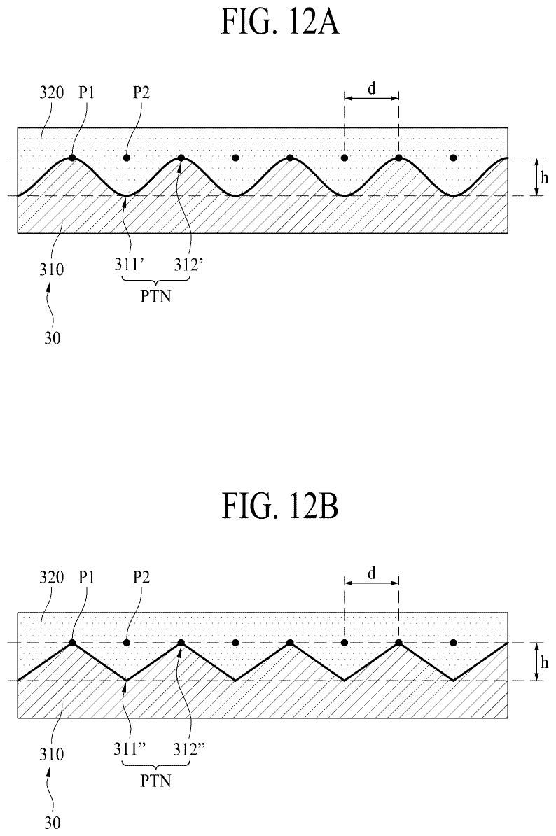

FIGS. 6A and 6B are views illustrating an external light image before passing through an optical member according to one embodiment of the present disclosure and an external light image after passing through the optical member, FIGS. 7A and 7B are comparison examples illustrating surface luminance of a display apparatus having no optical member, FIGS. 8A and 8B are views illustrating surface luminance of a display apparatus according to one embodiment of the present disclosure, FIG. 9A to 9C are images illustrating diffraction scattering dispersion patterns for each of the display apparatus according to one embodiment of the present disclosure and a display apparatus of a comparative example by intensity of external light, FIG. 10 is a graph illustrating that a color viewing angle of a display apparatus according to one embodiment of the present disclosure is compared with a color viewing angle of a display apparatus of a comparative example, and FIG. 11 is a graph illustrating that a luminance viewing angle of the display apparatus according to one embodiment of the present disclosure is compared with a luminance viewing angle of a display apparatus of a comparative example.

Referring to FIG. 2, the optical member 30 according to one example may include a first layer 310 including a pattern portion PTN having a plurality of concave portions 311 and a plurality of convex portions 312, and a second layer 320 covering the pattern portion PTN. The first layer 310 and the second layer 320 may have their respective refractive indexes different from each other. Thus, the first phase of light passing through the plurality of convex portions 312 of the external light incident on the optical member 30 may be different from the second phase of light passing through the plurality of concave portions 311.

A phase difference δ between light r₁ of the first phase and light r₂ of the second phase may satisfy Equation 1 as follows.

$$δ = ( N - 1 ) d sin θ + \vert Δ \vert$$

‘N’ is the sum of the number of the first points P1 and the number of the second points P2, ‘d’ is the distance between the first point P1 and the second point P2, |Δ| may be an absolute value of a phase difference between the light r₁ of the first phase and the light r₂ of the second phase in the first layer 310 and the second layer 320, and θ may be an emission angle of each of the light r₁ of the first phase and the light r₂ of the second phase based on the rear surface 310a of the first layer 310.

The absolute value |Δ| of the phase difference between the light r₁ of the first phase and the light r₂ of the second phase in the first layer 310 and the second layer 320 may satisfy Equation 2 as follows.

$$\vert Δ \vert = \vert ( {n}_{2} - {n}_{1} ) h / cos θ \vert$$

‘n₂’ is a second refractive index of the first layer 310, ‘n₁’ is a first refractive index of the second layer 320, ‘h’ is a depth (or maximum depth) of the concave portion 311, and θ may be an emission angle of each of the light r₁ of the first phase and the light r₂ of the second phase based on the rear surface 310a of the first layer 310.

As expressed in Equation 2, the absolute value |Δ| of the phase difference between the light r₁ of the first phase and the light r₂ of the second phase in the first layer 310 and the second layer 320 may be proportional to a difference between the second refractive index n₂ of the first layer 310 and the first refractive index n₁ of the second layer 320. Therefore, the phase difference δ between the light r₁ of the first phase and the light r₂ of the second phase may be increased as the difference between the second refractive index n₂ of the first layer 310 and the first refractive index n₁ of the second layer 320 is increased. As the phase difference δ between the light r₁ of the first phase and the light r₂ of the second phase is increased, the light passing through the first points P1 and the second points P2 may be more subdivided, so that the intensity of light may be further reduced. That is, the optical member 30 according to one embodiment of the present disclosure may reduce the intensity of external light by converting external light into diffractive light by using a phase difference in a medium of the first layer 310 and the second layer 320, which have their respective refractive indexes different from each other.

Meanwhile, when there is only a difference in the refractive index of each of the first layer 310 and the second layer 320 as expressed in Equation 2, a phase difference is generated between the plurality of first points P1 and the plurality of second points P2, and thus the second refractive index n₂ of the first layer 310 may be greater than or smaller than the first refractive index n₁ of the second layer 320. That is, the second refractive index n₂ of the first layer 310 may be different from the first refractive index n₁ of the second layer 320.

The absolute value |Δ| of the phase difference between the light r₁ of the first phase and the light r₂ of the second phase in the first layer 310 and the second layer 320 may satisfy Equation 3 as follows.

$$\vert Δ \vert = \vert {Δ}_{r 1} - {Δ}_{r 2} \vert$$

Δr₁ may be the first phase of light passing through the plurality of convex portions 312, and Δr₂ may be the second phase of light passing through the plurality of concave portions 311.

The first phase Δr₁ of light passing through the plurality of convex portions 312 may satisfy Equation 4 as follows.

$${Δ}_{r 1} = {n}_{2} t / cos θ$$

‘n₂’ is the second refractive index of the first layer 310, ‘t’ is the height of the convex portion 312 from the rear surface 310a of the first layer 310, and θ may be an emission angle of each of the light r₁ of the first phase and the light r₂ of the second phase based on the rear surface 310a of the first layer 310. That is, the first phase Δr₁ of light passing through the plurality of convex portions 312 may be a value obtained by multiplying a first length rₜ of light passing through the rear surface 130a of the first layer 130 from the first point P1 by the second refractive index n₂ of the first layer 310.

The second phase Δr₂ of light passing through the plurality of concave portions 311 may satisfy Equation 5 as follows.

$${Δ}_{r 2} = {n}_{1} h / cos θ + {n}_{2} ( t - h ) / cos θ$$

‘n₁’ is the first refractive index of the second layer 320, ‘h’ is the depth (or maximum depth) of the concave portion 311, ‘n₂’ is the second refractive index of the first layer 310, ‘t’ is the height (or maximum height) of the convex portion 312 from the rear surface 310a of the first layer 310, and θ may be an emission angle of each of the light r₁ of the first phase and the light r₂ of the second phase based on the rear surface 310a of the first layer 310. That is, the second phase Δr₂ of the light passing through the plurality of concave portions 311 may be a value obtained by multiplying each of the second refractive index n₂ of the first layer 310 and the first refractive index of the second layer 320 from a second length rₕ+rₜ₋ₕ of light passing through the rear surface 130a of the first layer 130 from the second point P2. In more detail, as expressed in Equation 5, the second phase Δr2 of light passing through the plurality of concave portions 311 may be a value obtained by multiplying the length rₕ of light passing through the upper surface of the first layer 130 from the second point P2 by the first refractive index n₂ of the second layer 320, multiplying the length rₜ₋ₕ of light passing through the rear surface 130a of the first layer 130 from the upper surface of the first layer 130 by the second refractive index n₁ of the first layer 310 and adding the multiplied values.

The optical member 30 according to one embodiment of the present disclosure is provided so that the first layer 310 having a plurality of concave portions 311 and a plurality of convex portions 312 and the second layer 320 having a refractive index different from that of the first layer 310 satisfy Equations 1 to 5, so that external light passing through a plurality of first points P1 and a plurality of second points P2 may be converted into diffractive light. Therefore, the first phase of light passing through the plurality of first points P1 may be different from the second phase of light passing through the plurality of second points P2.

As the first phase of light passing through the first points P1 and the second phase of light passing through the second points P2 are different from each other, constructive interference and/or destructive interference may be more generated than light having the same phase. As a result, since the optical member 30 according to one embodiment of the present disclosure may convert external light incident through the first layer 310 having a plurality of concave portions 311 and a plurality of convex portions 312 and the second layer 320 having a refractive index different from that of the first layer 310 into diffractive light, the intensity of emitted light may be reduced.

Referring to FIG. 5, external light EXL incident on the optical member 30 may pass through the plurality of first points P1 and the plurality of second points P2. As shown in FIG. 5, light passing through the plurality of first points P1 and the plurality of second points P2 may be subdivided by being converted into diffractive light by the plurality of first points P1 and the plurality of second points P2. The intensity of lights r_{N} of the subdivided phase may be reduced through constructive interference and/or destructive interference with each other.

FIG. 6A shows an image of external light before passing through the optical member according to one embodiment of the present disclosure, and FIG. 6B shows an image of external light after passing through the optical member according to one embodiment of the present disclosure.

As shown in FIG. 6A, the image of the external light before passing through the optical member 30 according to one embodiment of the present disclosure is seen as a clear image.

On the contrary, as shown in FIG. 6B, the image of the external light after passing through the optical member 30 according to one embodiment of the present disclosure is seen to be blurred. This is because the intensity of light is reduced while external light is passing through the optical member 30 of the present disclosure. In more detail, the external light is converted into diffractive light while passing through the first points P1 and the second points P2 of the optical member 30, so that the external light may be subdivided, and the lights of the subdivided phase may be subjected to constructive interference and/or destructive interference with each other, so that the intensity of the light may be reduced. Therefore, as shown in FIG. 6B, the optical member 30 according to one embodiment of the present disclosure may reduce the intensity of external light.

The optical member 30 according to one embodiment of the present disclosure, as shown in FIG. 1, may be coupled to the display panel 10 according to one embodiment of the present disclosure. Therefore, the display apparatus 1 according to one embodiment of the present disclosure may be implemented in such a manner that the optical member 30 and the display panel 10 are combined with each other. The optical member 30 according to one embodiment of the present disclosure is coupled to one side or the other side of the display panel 10, so that the intensity of external light incident on the display panel 10 may be reduced. Therefore, the display apparatus 1 according to one embodiment of the present disclosure may suppress or minimize occurrence of the diffraction pattern of the reflective light generated by the light extraction portion 140, or suppress or minimize occurrence of a radial rainbow pattern and a radial circular ring pattern of the reflective light due to non-regularity or randomness of the diffraction pattern of the reflective light.

Also, since external light may be subdivided by the optical member 30, the display apparatus 1 according to one embodiment of the present disclosure may suppress or minimize occurrence of a radial rainbow pattern and a radial circular ring pattern due to external light, whereby real black visibility in a non-driving or off state may be implemented.

FIGS. 7A and 7B are comparative examples showing surface luminance of a display apparatus having no optical member. (a) of FIG. 7A shows surface luminance seen with the naked eye, and (b) of FIG. 7A shows surface luminance measured by a CCD camera which is a luminance meter.

As shown in (a) of FIG. 7A and (b) of FIG. 7A, in case of a display apparatus having no optical member, due to a non-regularity or randomness of a diffraction pattern of reflective light as external light is reflected to a pixel circuit, a radial rainbow pattern and a radial circular ring pattern may be identified with a CCD camera and the naked eye based on the center C of reflective light.

FIG. 7B shows a luminance graph of a cross section of lines II-II′ and III-III′ shown in (b) of FIG. 7A. In FIG. 7B, a horizontal axis is a length spaced apart from the center C of the reflective light, and a vertical axis is luminance. L1 is a luminance graph of a cross-section of line II-II′ shown in (b) of FIG. 7A, and L2 is a luminance graph of a cross-section of line III-III′ shown in (b) of FIG. 7A. As shown in FIG. 7B, each of L1 and the L2 may have luminance lowered while having peaks at a predetermined interval toward left and right sides based on the center C of the reflective light. In addition, since L2 is spaced to be farther than L1 from the center C of the reflective light, L2 may have luminance lower than that of L1.

On the contrary, as shown in FIGS. 8A and 8B, in case of the display apparatus 1 according to one embodiment of the present disclosure, since the optical member 30 is disposed on one side or the other side of the display panel 10, the intensity of light incident on the display panel 10 may be reduced. In detail, in case of the display apparatus 1 according to one embodiment of the present disclosure, since the intensity of external light incident on the light extraction portion 140 by the optical member 30 may be reduced, the diffraction pattern of the reflective light generated by the light extraction portion 140 may be suppressed or minimized, or occurrence of a radial rainbow pattern and a radial circular ring pattern of the reflective light may be suppressed or minimized due to non-regularity or randomness of the diffraction pattern of the reflective light. Therefore, as shown in (a) of FIG. 8A and (b) of FIG. 8A, a radial rainbow pattern and a radial circular ring pattern may not be identified by the CCD camera and the naked eye based on the center C of the reflective light.

FIG. 8B shows a luminance graph of a cross-section of lines IV-IV′ and V-V′ shown in (b) of FIG. 8A. In FIG. 8B, a horizontal axis is a length spaced apart from the center C of the reflective light, and a vertical axis is luminance. L3 is a luminance graph of a cross-section of line IV-IV′ shown in (b) of FIG. 8A, and LA is a luminance graph of a cross-section of line V-V′ shown in (b) of FIG. 8A. As shown in FIG. 8B, L3 may have luminance lowered toward left and right sides based on the center C of the reflective light. However, L3 does not form peaks at a predetermined interval unlike L1. In addition, even though L4 is spaced apart from left and right sides based on the center C of the reflective light, luminance is uniformly maintained without being almost changed. This is because the optical member 30 according to one embodiment of the present disclosure reduces the intensity of external light incident on the display panel 10, thereby suppressing or minimizing the diffraction pattern of reflective light generated by the light extraction portion 140, or suppressing or minimizing occurrence of a radial rainbow pattern and a radial circular ring pattern of the reflective light due to non-regularity or randomness of the diffraction pattern of the reflective light. Therefore, luminance of L3 may be uniformly lowered based on the center C of the reflective light, and luminance of L4 may be almost uniformly maintained even when it is spaced apart from the left and right sides based on the center C of the reflective light.

FIGS. 9A to 9C are images showing diffraction scattering dispersion patterns for each of the display apparatus 1 according to one embodiment of the present disclosure and the display apparatus 2 according to the comparison example for each intensity of external light.

The display apparatus 2 of the comparative example may refer to a display apparatus in which the optical member 30 according to one embodiment of the present disclosure is not provided.

FIG. 9A shows a diffraction scattering dispersion pattern for each of the display apparatus 1 according to the present disclosure and the display apparatus 2 of the comparison example at illuminance of about 49800 lux, FIG. 9B shows a diffraction scattering dispersion pattern for each of the display apparatus 1 according to the present disclosure and the display apparatus 2 of the comparative example at illuminance of about 76200 lux, and FIG. 9C shows a diffraction scattering dispersion pattern for each of the display apparatus 1 according to the present disclosure and the display apparatus 2 according to the comparative example at illuminance of about 88600 lux.

First, as shown in FIG. 9A, in case of weak illuminance of about 49800 lux, since the display apparatus 2 of the comparative example is not provided with an optical member, diffraction scattering dispersion patterns RP (or rainbow patterns RP) spaced apart from each other at a predetermined interval may be identified with the naked eye due to non-regularity or randomness of the diffraction pattern of the reflective light as the external light is reflected in the pixel circuit. As shown in FIG. 9A, the rainbow patterns RP are spread by being spaced apart from each other. This is because that the patterns RP are seen as black at a place where waves meet each other and are seen as rainbow due to refraction of waves at a place where the waves do not meet each other due to constructive interference and/or destructive interference caused by wave properties of light when diffusion according to two or more slits occurs. This may be equally applied to the display apparatus 2 of the comparative example shown in each of FIGS. 9B and 9C.

On the contrary, the display apparatus 1 according to one embodiment of the present disclosure is provided with the optical member 30 so that light incident on the display panel 10 may be converted into diffractive light. In detail, in case of the display apparatus 1 according to one embodiment of the present disclosure, external light incident on the light extraction portion 140 by the optical member 30 may be subdivided into diffractive light, and the intensity of light may be reduced through constructive interference and/or destructive interference of the subdivided diffractive lights. Therefore, the display apparatus 1 according to one embodiment of the present disclosure may suppress or minimize the diffraction pattern of reflective light generated by the light extraction portion 140, or suppress or minimize occurrence of a radial rainbow pattern and a radial circular ring pattern due to non-regularity or randomness of the diffraction pattern of the reflective light. Therefore, as shown in FIG. 9A, a rainbow pattern or a circular ring pattern may not be identified with the naked eye at a weak illuminance in the display apparatus 1 according to one embodiment of the present disclosure.

Then, as shown in FIG. 9B, in case of intermediate illuminance of about 476200 lux, since the display apparatus 2 of the comparative example is not provided with an optical member, diffraction scattering dispersion patterns RP (or rainbow patterns RP) spaced apart from each other at a predetermined interval may be identified with the naked eye due to non-regularity or randomness of the diffraction pattern of the reflective light as the external light is reflected in the pixel circuit.

On the contrary, the display apparatus 1 according to one embodiment of the present disclosure is provided with the optical member 30 so that the intensity of light incident on the display panel 10 may be reduced. In detail, in case of the display apparatus 1 according to one embodiment of the present disclosure, since the intensity of external light incident on the light extraction portion 140 by the optical member 30 may be reduced, the diffraction pattern of the reflective light generated by the light extraction portion 140 may be suppressed or minimized, or occurrence of a radial rainbow pattern and a radial circular ring pattern due to non-regularity or randomness of the diffraction pattern of the reflective light may be suppressed or minimized. Therefore, as shown in FIG. 9B, a rainbow pattern or a circular ring pattern may not be identified with the naked eye even at intermediate illuminance in the display apparatus 1 according to one embodiment of the present disclosure.

Then, as shown in FIG. 9C, in case of strong illuminance of about 88600 lux, since the display apparatus 2 of the comparative example is not provided with an optical member, diffraction scattering dispersion patterns RP (or rainbow patterns RP) spaced apart from each other at a predetermined interval may be more identified with the naked eye due to non-regularity or randomness of the diffraction pattern of the reflective light than the intermediate illuminance as the external light is reflected in the pixel circuit.

On the contrary, the display apparatus 1 according to one embodiment of the present disclosure is provided with the optical member 30 so that the intensity of light incident on the display panel 10 may be reduced. In detail, in case of the display apparatus 1 according to one embodiment of the present disclosure, since the intensity of external light incident on the light extraction portion 140 by the optical member 30 may be reduced, the diffraction pattern of the reflective light generated by the light extraction portion 140 may be suppressed or minimized, or occurrence of a radial rainbow pattern and a radial circular ring pattern due to non-regularity or randomness of the diffraction pattern of the reflective light may be suppressed or minimized. Therefore, as shown in FIG. 9C, a rainbow pattern or a circular ring pattern may not be identified with the naked eye even at strong illuminance in the display apparatus 1 according to one embodiment of the present disclosure.

Consequently, in the display apparatus 1 according to one embodiment of the present disclosure, even in case from weak illuminance to strong illuminance, that is, even in case that external light is weak or strong, occurrence of a rainbow pattern or a circular ring pattern, such as a diffraction scattering dispersion pattern, may be suppressed or minimized through the optical member 30, whereby real black visibility may be implemented in a non-driving or off state.

FIG. 10 is a graph illustrating that a color viewing angle of a display apparatus 1 according to one embodiment of the present disclosure is compared with a color viewing angle of a display apparatus of a comparative example, that is, the display apparatus having no optical member.

Referring to FIG. 10, a horizontal axis represents a horizontal angle ° based on a pixel that emits light, and a vertical axis represents a color viewing angle. LN1 is a graph of a color viewing angle according to an angle of a display apparatus of a comparative example, and LN2 is a graph of a color viewing angle according to an angle of the display apparatus 1 according to one embodiment of the present disclosure. As shown in FIG. 10, there is a difference of 0.025 or less in a color viewing angle based on the angle between the display apparatus 1 according to one embodiment of the present disclosure and the display apparatus of the comparative example. That is, it may be noted that there is almost no difference in the color viewing angle based on the angle between the display apparatus 1 according to one embodiment of the present disclosure and the display apparatus of the comparative example.

Therefore, the display apparatus 1 according to one embodiment of the present disclosure has almost no change in a color viewing angle as compared with the display apparatus having no optical member, and may suppress or minimize occurrence of a radial rainbow pattern and a radial circular ring pattern of reflective light.

FIG. 11 is a graph illustrating that a luminance viewing angle of the display apparatus 1 according to one embodiment of the present disclosure is compared with a luminance viewing angle of a display apparatus of a comparative example, that is, a luminance viewing angle of a display apparatus having no optical member.

Referring to FIG. 11, a horizontal axis represents a horizontal angle ° based on a pixel that emits light, and a vertical axis represents a luminance viewing angle. LN3 is a graph of a luminance viewing angle based on an angle of a display apparatus of a comparative example, and LN4 is a graph of a luminance viewing angle based on an angle of the display apparatus 1 according to one embodiment of the present disclosure. As shown in FIG. 11, there is a difference of 3 or less in a luminance viewing angle based on the angle between the display apparatus 1 according to one embodiment of the present disclosure and the display apparatus of the comparative example. That is, it may be noted that there is almost no difference in the luminance viewing angle based on the angle between the display apparatus 1 according to one embodiment of the present disclosure and the display apparatus of the comparative example.

Therefore, the display apparatus 1 according to one embodiment of the present disclosure has almost no change in a luminance viewing angle as compared with the display apparatus having no optical member, and may suppress or minimize occurrence of a radial rainbow pattern and a radial circular ring pattern of reflective light.

As a result, the display apparatus 1 according to one embodiment of the present disclosure is capable of converting external light into diffractive light without luminance deterioration and distortion of display quality as compared with the display apparatus having no optical member. Therefore, the display apparatus 1 according to one embodiment of the present disclosure may reduce degradation of black visibility characteristics, which is caused by reflection of external light, and thus may implement real black in a non-driving or off state.

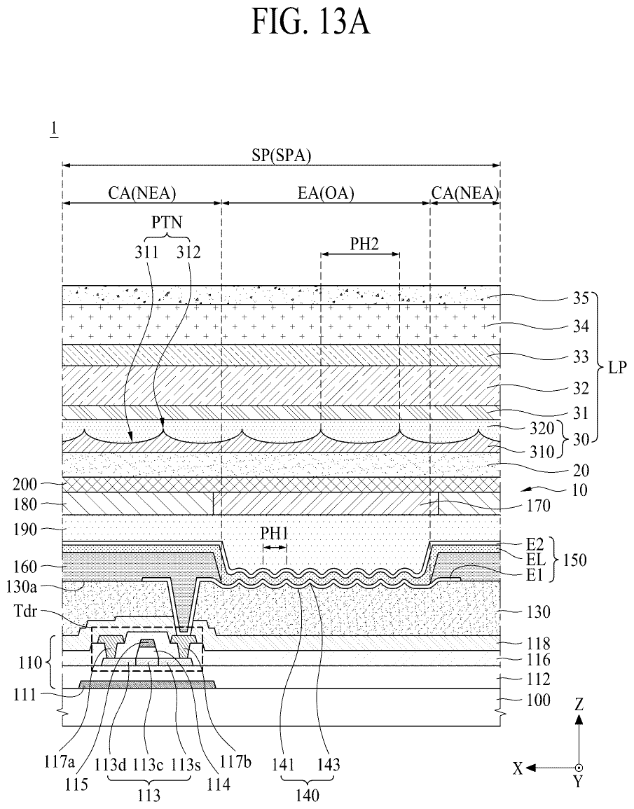

FIGS. 12A and 12B are views illustrating various shapes of a pattern portion included in an optical member of a display apparatus according to one embodiment of the present disclosure.

Referring to FIG. 12A, the pattern portion PTN of the optical member 30 according to one embodiment of the present disclosure may be provided in a curved pattern having a certain curvature or a wave pattern. The plurality of first points P1 may be disposed on a mountain portion 312′ (or peak portion 312′) corresponding to the plurality of convex portions 312. The plurality of second points P2 may be disposed between the plurality of first points P1 above a valley portion 311′ corresponding to the plurality of concave portions 311. That is, the second points P2 overlaps with the valley portion 311′. The first point P1 and the second point P2 may be spaced apart from each other at the first distance ‘d.’ A maximum depth of the plurality of valley portions 311′ may be ‘h.’ Therefore, as shown in FIG. 12A, even though the pattern portion PTN of the optical member 30 is provided as a curved pattern, the pattern portion PTN is provided to satisfy the aforementioned Equations 1 to 5, so that the intensity of external light incident on the display panel 10 may be reduced. Therefore, the display apparatus 1 according to one embodiment of the present disclosure may suppress or minimize the diffraction pattern of reflective light generated by the light extraction portion 140, or suppress or minimize occurrence of a radial rainbow pattern and a radial circular ring pattern due to non-regularity or randomness of the diffraction pattern of the reflective light.

Referring to FIG. 12B, the pattern portion PTN of the optical member 30 according to one embodiment of the present disclosure may be provided in a zigzag pattern. In other embodiments, the pattern portion PTN of the optical member 30 may also be provided in a jagged pattern. Another form that the pattern portion PTN of the optical member 30 can be provided is in a triangular wave pattern. The plurality of first points P1 may be disposed at an upper vertex 312″ corresponding to the plurality of convex portions 312. The plurality of second points P2 may be disposed between the plurality of first points P1 above a lower vertex 311″ corresponding to the plurality of concave portions 311. The first point P1 and the second point P2 may be spaced apart from each other at the first distance ‘d.’ A maximum depth of a plurality of lower vertexes 311″ may be ‘h.’ Therefore, as shown in FIG. 12B, even though the pattern portion PTN of the optical member 30 is provided in a zigzag pattern, the pattern portion PTN is provided to satisfy the aforementioned Equations 1 to 5, so that the intensity of external light incident on the display panel 10 may be reduced. Therefore, the display apparatus 1 according to one embodiment of the present disclosure may suppress or minimize the diffraction pattern of the reflective light generated by the light extraction portion 140, or suppress or minimize occurrence of a radial rainbow pattern and a radial circular ring pattern due to non-regularity or randomness of the diffraction pattern of the reflective light.

As a result, the pattern portion PTN of the optical member 30 according to one embodiment of the present disclosure is provided as any one of a curved pattern, a zigzag pattern, and a lens-shaped pattern to satisfy the Equations 1 to 5, so that the external light may be converted into diffractive light and segmented, whereby occurrence of a radial rainbow pattern and a radial circular ring pattern due to external light may be suppressed or minimized. Therefore, the optical member 30 according to one embodiment of the present disclosure may implement real black visibility in a non-driving or off state.

FIG. 13A is a view illustrating a display apparatus according to the first embodiment of the present disclosure, and FIG. 13B is a view illustrating a modified example of a display apparatus according to the first embodiment of the present disclosure.

Referring to FIG. 13A, the display apparatus 1 according to the first embodiment of the present disclosure may include a display panel 10 of a top emission type, and an optical panel LP coupled to an upper side of the display panel 10 through an adhesive 20.

The optical panel LP may include the optical member 30 that includes the first layer 310 and the second layer 320 described above. The optical panel LP according to one example may further include a phase delay layer 31, a first protective layer 32, a polarization conversion layer 33, a second protective layer 34, and an anti-reflective film 35 in addition to the optical member 30.

As shown in FIG. 13A, the plurality of concave portions 311 and the plurality of convex portions 312, which are included in the first layer 310 may be formed in the light emission area EA and the non-emission area NEA, but the present disclosure is not limited thereto, and the plurality of concave portions 311 and the plurality of convex portions 312 may be formed only in the light emission area EA when the intensity of external light incident on the light extraction portion 140 may be reduced.

Referring back to FIG. 13A, the adhesive 20 for coupling the display panel 10 with the optical panel LP may be disposed between the opposing substrate 200 and the first layer 310 of the optical member 30. The adhesive 20 may be formed of a transparent adhesive material having high light transmittance. For example, the adhesive 20 may include at least one of PSA or OCA.

The phase delay layer 31 may be disposed on the second layer 320 of the optical member 30. The phase delay layer 31, in operation or during use, delays a phase of the external light by a selected amount. The phase delay layer 31 according to one example is for delaying a phase of light as much as ¼λ. The phase delay layer 31 may be a ¼λ wavelength plate or a quarter wave plate (QWP).

The first protective layer 32 may be disposed on the phase delay layer 31. The first protective layer 32 is for protecting the polarization conversion layer 33. The first protective layer 32 may be provided to be thicker than the polarization conversion layer 33, thereby protecting the polarization conversion layer 33 from moisture permeation. Surface coating having characteristics such as scattering, hardness enhancement, anti-reflection, and low reflection may be performed on the surface of the first protective layer 32. For example, the first protective layer 32 may be tri-acetate cellulose (TAC).

The polarization conversion layer 33 may be disposed on the first protective layer 32. The polarization conversion layer 33 is for converting non-polarized light into linearly polarized light. For example, the polarization conversion layer 33 may be poly vinyl alcohol (PVA).

The second protective layer 34 may be disposed on the polarization conversion layer 33. The second protective layer 34 is for protecting the polarization conversion layer 33. The second protective layer 34 may be provided to be thicker than the polarization conversion layer 33, thereby protecting the polarization conversion layer 33 from moisture permeation. Surface coating having characteristics such as scattering, hardness enhancement, anti-reflection, and low reflection may be performed on the surface of the second protective layer 34. For example, the second protective layer 34 may be tri-acetate cellulose (TAC).

The anti-reflective film 35 may be disposed on the second protective layer 34. The anti-reflective film 35 may be a film for preventing external light from being reflected toward the circuit element. Therefore, the anti-reflective film 35 may be disposed at the outermost side of the optical panel LP on which external light is directly incident.

The phase delay layer 31, the first protective layer 32, the polarization conversion layer 33, the second protective layer 34, and the anti-reflective film 35 may be represented by an OLED polarizing plate.

The display apparatus 1 according to the first embodiment of the present disclosure is provided with a display panel 10 of a top emission type, and an optical panel LP that includes an optical member 30 provided at an upper side of the display panel 10, thereby polarizing and phase-converting external light to minimize reflection of external light. In addition, the display apparatus 1 according to the first embodiment of the present disclosure may reduce the intensity of external light incident on the display panel 10 through the optical member 30, thereby minimizing or reducing occurrence of a radial rainbow pattern and a radial circular ring pattern according to the diffraction pattern of the reflective light generated due to destructive interference and/or constructive interference of light caused by reflection of external light.

Referring back to FIG. 13A, in the display apparatus 1 according to the first embodiment of the present disclosure, one of the plurality of concave portions 311 may overlap multiple convex patterns 143 of the plurality of convex patterns 143. For example, in the display apparatus 1 according to the first embodiment of the present disclosure, a pitch PH1 of the plurality of convex patterns 143 may be smaller than a pitch PH2 of the plurality of convex portions 312. Therefore, the number of the light extraction portions 140 may be greater than the number of the pattern portions PTN based on the light emission area EA. Therefore, in the display apparatus 1 according to FIG. 13A, the pattern portion PTN (or the plurality of concave portions 311 and the plurality of convex portions 312) may be easily formed without defects as compared with the case that the pitch of the plurality of convex patterns 143 is greater than the pitch of the plurality of convex portions 312.

Referring to FIG. 13B, a modified example of the display apparatus 1 according to the first embodiment of the present disclosure is the same as the display apparatus according to FIG. 13A described above, except that the pitch PH3 of the plurality of convex patterns 143 is greater than the pitch PH4 of the plurality of convex portions 312. Therefore, the same reference numerals are assigned to the same configurations, and only different configurations will be described below.

In case of the display apparatus according to FIG. 13A described above, the pitch PH1 of the plurality of convex patterns 143 may be smaller than the pitch PH2 of the plurality of convex portions 312. Therefore, the display apparatus 1 according to FIG. 13A may easily form the pattern portion PTN (or the plurality of concave portions 311 and the plurality of convex portions 312) as compared with the case that the pitch of the plurality of convex patterns 143 is greater than the pitch of the plurality of convex portions 312.

On the contrary, in case of the display apparatus according to FIG. 13B, the pitch PH3 of the plurality of convex patterns 143 may be greater than the pitch PH4 of the plurality of convex portions 311. That is, the pitch of the plurality of concave portions 311 may be smaller than the pitch PH3 of the plurality of concave patterns. Therefore, since the external light incident on the light extraction portion 140 may be further subdivided by the optical member 30, the display apparatus 1 according to FIG. 13B may maximize the reduction in the radial rainbow pattern and the radial circular ring pattern according to the diffraction pattern of the reflective light.

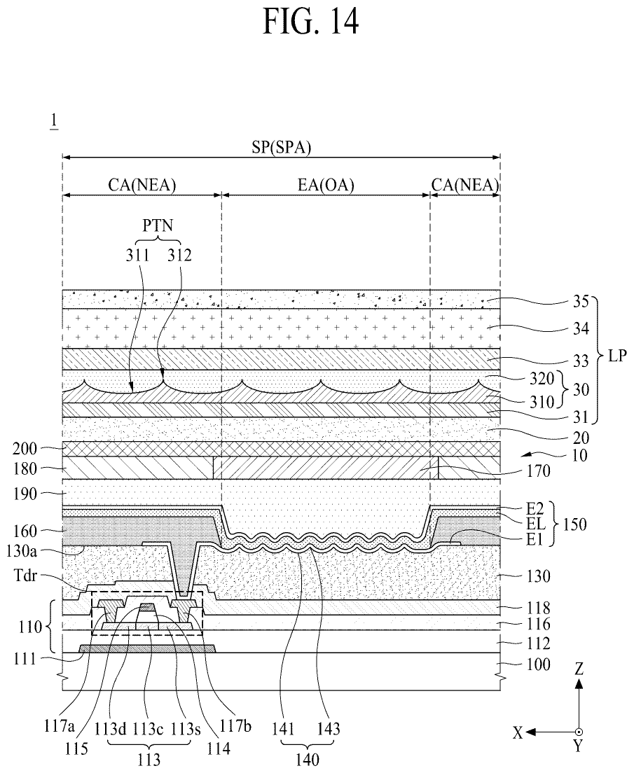

FIG. 14 is a view illustrating a display apparatus according to the second embodiment of the present disclosure.

Referring to FIG. 14, the display apparatus 1 according to the second embodiment of the present disclosure is the same as the display apparatus according to FIG. 13A except that the configuration of the optical panel LP is changed. Therefore, the same reference numerals will be given to the same elements as those of FIG. 13A, and the following description will be based on differences from FIG. 13A.

In case of the display apparatus according to FIG. 13A, the optical member 30, the phase delay layer 31, the first protective layer 32, the polarization conversion layer 33, the second protective layer 34, and the anti-reflective film 35 are sequentially stacked on the upper surface of the display panel 10, whereby reflectance and intensity of external light incident on the display panel 10 may be reduced.

On the contrary, in case of the display apparatus according to FIG. 14, the phase delay layer 31 included in the optical panel LP is disposed below the first layer 310 of the optical member 30, and the polarization conversion layer 33 is disposed on the second layer 320 of the optical member 30. The protective layer 34 (or the second protective layer 34) is disposed on the polarization conversion layer 33, and the anti-reflective film 35 is disposed on the protective layer 34. Therefore, the phase delay layer 31 of the optical panel LP may be coupled to the upper surface of the display panel 10 (or the upper surface of the opposing substrate 200) through the adhesive 20. Unlike the display apparatus of FIG. 13A, the display apparatus 10 according to FIG. 14 may include only one protective layer between the anti-reflective film 35 and the polarization conversion layer 33. Therefore, the display apparatus 10 according to FIG. 14 may be easily manufactured as only one protective layer is provided, and transmittance of light emitted from the light emitting element layer 150 may be improved as much as 7% or more, whereby luminance may be improved.

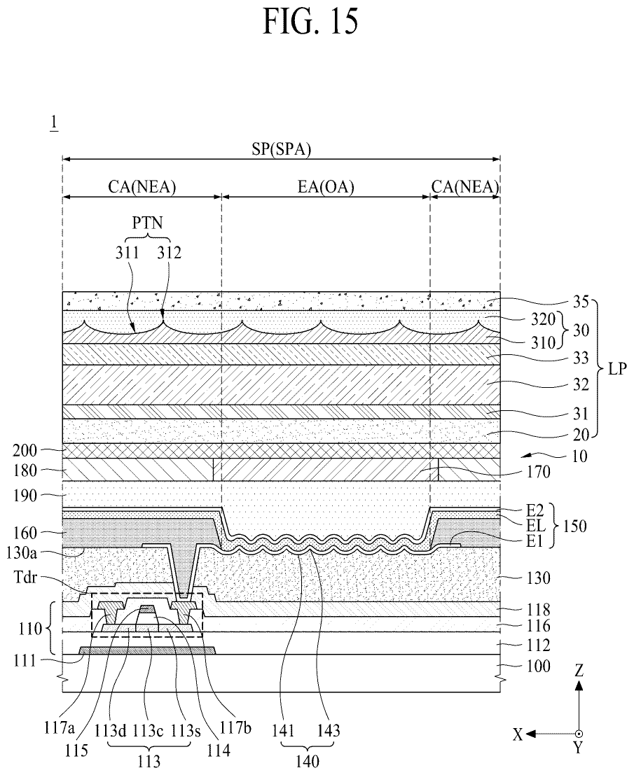

FIG. 15 is a view illustrating a display apparatus according to the third embodiment of the present disclosure.

Referring to FIG. 15, the display apparatus 1 according to the third embodiment of the present disclosure is the same as the display apparatus according to FIG. 13A except that the configuration of the optical panel LP is changed. Therefore, the same reference numerals will be given to the same elements as those of FIG. 13A, and the following description will be based on differences from FIG. 13A.

In case of the display apparatus according to FIG. 13A, the optical member 30, the phase delay layer 31, the first protective layer 32, the polarization conversion layer 33, the second protective layer 34 and the anti-reflective film 35 are sequentially stacked on the upper surface of the display panel 10, whereby reflectance and intensity of external light incident on the display panel 10 may be reduced.

On the contrary, in case of the display apparatus according to FIG. 15, the anti-reflective film 35 included in the optical panel LP is disposed on the second layer 310 of the optical member 30, and the polarization conversion layer 33 is disposed below the first layer 310 of the optical member 30. The protective layer 32 (or the first protective layer 32) is disposed below the polarization conversion layer 33, and the phase delay layer 31 is disposed below the protective layer 32. Therefore, the phase delay layer 31 of the optical panel LP may be coupled to the upper surface of the display panel 10 (or the upper surface of the opposing substrate 200) through the adhesive 20. Unlike the display apparatus of FIG. 13A, the display apparatus 1 according to FIG. 15 may include only one protective layer between the polarization conversion layer 33 and the phase delay layer 31. Therefore, the display apparatus 1 according to FIG. 15 may be easily manufactured as only one protective layer is provided, and transmittance of light emitted from the light emitting element layer 150 may be improved as much as 7% or more, whereby luminance may be improved.

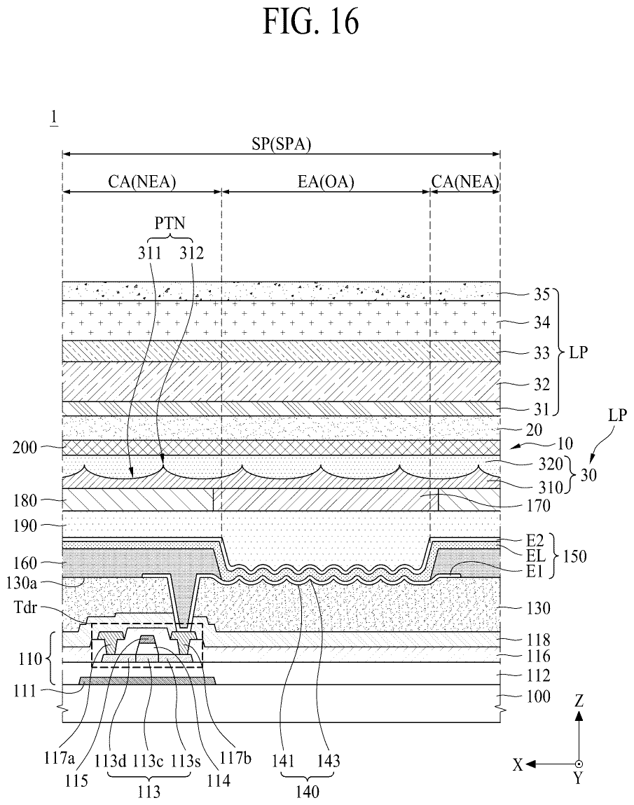

FIG. 16 is a view illustrating a display apparatus according to the fourth embodiment of the present disclosure.

Referring to FIG. 16, the display apparatus 1 according to the fourth embodiment of the present disclosure is the same as the display apparatus according to FIG. 13A except that the optical panel LP (or the optical member 30) is formed inside the display panel 10. Therefore, the same reference numerals will be given to the same elements as those of FIG. 13A, and the following description will be based on differences from FIG. 13A.

In case of the display apparatus according to FIG. 13A, the optical member 30, the phase delay layer 31, the first protective layer 32, the polarization conversion layer 33, the second protective layer 34 and the anti-reflective film 35 are sequentially stacked on the upper surface of the display panel 10, whereby reflectance and intensity of external light incident on the display panel 10 may be reduced.

On the contrary, in case of the display apparatus according to FIG. 16, the optical panel LP (or the optical member 30) is formed inside the display panel 10. The optical member 30 according to one example may be disposed between the color filter layer 170 and the opposing substrate 200 of the display panel 10. The phase delay layer 31, the first protective layer 32, the polarization conversion layer 33, the second protective layer 34, and the anti-reflective film 35 of the optical panel LP may be sequentially stacked on the upper surface (or the outside) of the display panel 10. Therefore, the phase delay layer 31 of the optical panel LP may be coupled to the upper surface of the display panel 10 (or the upper surface of the opposing substrate 200) through the adhesive 20. Unlike the display apparatus of FIG. 13A, in the display apparatus 1 according to FIG. 16, the optical member 30 is formed inside the display panel 10 so that the intensity of external light may be reduced by only the display panel 10, whereby occurrence of diffraction dispersion patterns may be blocked. Therefore, in the display apparatus 1 according to FIG. 16, a polarizing plate or a polarizing film (or a known polarizing plate or polarizing film), which is generally used, may be applied to the outside of the display panel 10, whereby versatility may be improved.

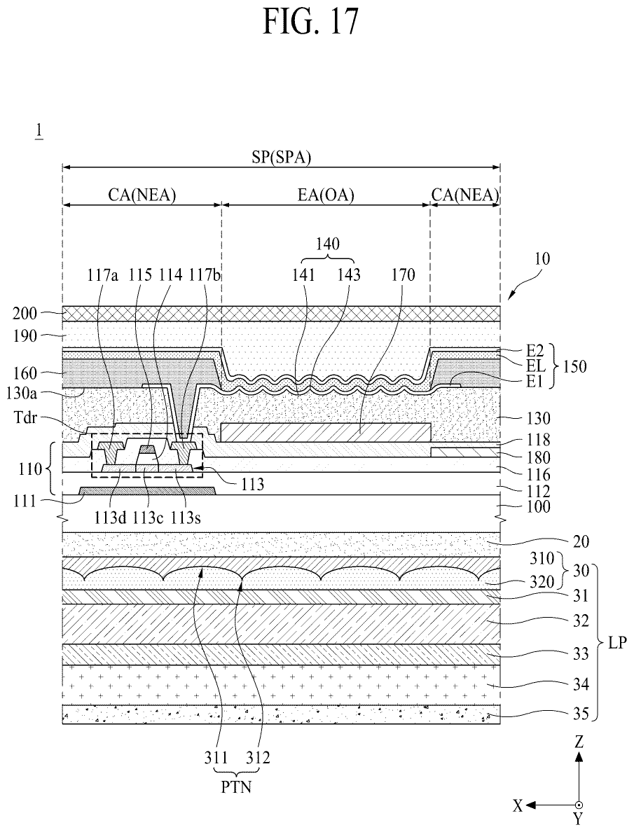

FIG. 17 is a view illustrating a display apparatus according to the fifth embodiment of the present disclosure.

Referring to FIG. 17, the display apparatus 1 according to the fifth embodiment of the present disclosure is the same as the display apparatus according to FIG. 13A except that the display panel 10 is changed to a bottom emission type and the optical panel LP is coupled to the lower side of the display panel 10. Therefore, the same reference numerals will be given to the same elements as those of FIG. 13A, and the following description will be based on differences from FIG. 13A.

In case of the display apparatus according to FIG. 13A described above, the optical member 30, the phase delay layer 31, the first protective layer 32, the polarization conversion layer 33, the second protective layer 34, and the anti-reflective film 35 are sequentially stacked on the upper surface of the display panel 10, whereby reflectance and intensity of external light incident on the display panel 10 may be reduced.

On the contrary, in case of the display apparatus according to FIG. 17, the display panel 10 is implemented in a bottom emission type. Therefore, the optical panel LP may be coupled to a direction in which light is emitted from the display panel 10, that is, the lower side of the display panel 10 through the adhesive 20.

The display apparatus 1 according to FIG. 17 is a top emission type, and thus the color filter layer 170 may be disposed between the overcoat layer 130 and the passivation layer 118. Therefore, the color filter layer 170 may color-convert light emitted from the light emitting element layer 150 and directed toward the lower surface of the substrate 100. In addition, since the display apparatus 1 according to FIG. 17 is a bottom emission type, the black matrix 180 may be disposed between the passivation layer 118 and the interlayer insulating layer 116 without overlapping the color filter layer 170. Therefore, the black matrix 180 may be disposed between adjacent subpixels SP to prevent color mixture from occurring.

Meanwhile, since the display apparatus 1 according to FIG. 17 is a bottom emission type, the second electrode E2 may be provided as a reflective electrode, and the first electrode E1 may be provided as a translucent electrode or a transparent electrode.

In case of the display apparatus according to FIG. 17, the external light is incident through the lower side of the display panel 10, and thus the stacking order of the optical panels LP may be arranged in the reverse order of the optical panel of the display apparatus according to FIG. 13A. As shown in FIG. 17, the first layer 310 of the optical member 30 may be coupled to the lower surface of the substrate 100 through the adhesive 20. The second layer 320 having a refractive index different from that of the first layer 310 may be disposed below the first layer 310, and the phase delay layer 31 may be disposed below the second layer 320. In addition, the first protective layer 32 may be disposed below the phase delay layer 31, and the polarization conversion layer 33 may be disposed below the first protective layer 32. The second protective layer 34 may be disposed below the polarization conversion layer 33, and the anti-reflective film 35 may be disposed below the second protective layer 34.

Therefore, in case of the display apparatus according to FIG. 17, the optical panel LP disposed on the lower side of the display panel 10 may reduce reflectance and intensity of external light incident on the lower surface of the display panel 10. Therefore, the display apparatus 1 according to FIG. 17 may suppress or minimize the diffraction pattern of the reflective light generated by the light extraction portion 140, or suppress or minimize occurrence of a radial rainbow pattern and a radial circular ring pattern due to non-regularity or randomness of the diffraction pattern of the reflective light.

Also, the display apparatus 1 according to FIG. 17, occurrence of the radial rainbow pattern and the radial circular ring pattern due to external light may be suppressed or minimized by the optical panel LP coupled to the lower side of the display panel 10, whereby real black visibility in a non-driving or off state may be implemented.

According to the present disclosure, the following advantageous effects may be obtained.

The optical member according to the present disclosure may include a first layer, which includes a pattern portion having a plurality of concave portions and a plurality of convex portions, and a second layer having a refractive index different from that of the first layer, so that the light passing through the first layer and the second layer may be converted into the diffractive light to reduce the intensity of the external light through interference of the diffractive light.

In the display apparatus according to the present disclosure, as each of the plurality of subpixels includes a light extraction portion that includes a plurality of concave patterns and a plurality of convex patterns, light extraction efficiency of light emitted from the light emitting element layer may be improved.

In the display apparatus according to the present disclosure, since light extraction efficiency may be improved through the light extraction portion, the same light emission efficiency may be obtained even at low power or light emission efficiency may be more improved than the display apparatus having no light extraction portion, whereby overall power consumption may be reduced.

The display apparatus according to the present disclosure is provided with the optical member, so that the intensity of the external light incident on the light extraction portion may be reduced by the optical member, whereby the diffraction pattern of the reflective light generated by the light extraction portion may be suppressed or minimized, or occurrence of the radial rainbow pattern and the radial circular ring pattern of the reflective light may be suppressed or minimized due to non-regularity or randomness of the diffraction pattern of the reflective light.

Since the external light may be subdivided by the optical member in the display apparatus according to the present disclosure, occurrence of the radial rainbow pattern and the radial circular ring pattern due to the external light may be suppressed or minimized, whereby real black visibility may be implemented in a non-driving or off-state.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An optical member comprising:
a first layer including a pattern portion having a plurality of concave portions and a plurality of convex portions between the plurality of concave portions; and
a second layer on the first layer, the second layer covering the pattern portion,
wherein the first layer and the second layer have their respective refractive indexes different from each other, and
wherein, in operation, a first phase of light passing through the plurality of convex portions is different from a second phase of light passing through the plurality of concave portions.

2. The optical member of claim 1, wherein the first layer includes a plurality of first points on an uppermost side of each of the plurality of convex portions,
wherein the second layer includes a plurality of second points between the plurality of first points, and
wherein the first phase of the light passing through the plurality of first points is different from the second phase of the light passing through the plurality of second points.

3. The optical member of claim 2, wherein the plurality of first points is at a same height as the plurality of second points with respect to a rear surface of the first layer.

4. The optical member of claim 2, wherein each of the plurality of second points is at the center between adjacent first points of the plurality of first points.

5. The optical member of claim 2, wherein the light of the first phase, which passes through the first layer, and the light of the second phase, which passes through the second layer, have reduced intensity of light based on at least one of constructive interference or destructive interference.

6. The optical member of claim 5, wherein the intensity of light is further reduced as a difference in a refractive index between the first layer and the second layer is increased.

7. The optical member of claim 1, wherein an upper surface of the second layer is planar.

8. The optical member of claim 2, wherein a phase difference δ between the light of the first phase and the light of the second phase satisfies δ=(N−1)d sin θ+|Δ|,
where ‘N’ is a sum of the number of the first points and the number of the second points, ‘d’ is a distance between the first point and the second point, |Δ| is an absolute value of a phase difference between the light of the first phase and the light of the second phase in the first layer and the second layer, and θ is an emission angle of each of the light of the first phase and the light of the second phase with respect to a rear surface of the first layer.

9. The optical member of claim 8, wherein the absolute value |Δ| of the phase difference between the light of the first phase and the light of the second phase in the first layer and the second layer satisfies |Δ|=|(n₂−n₁)h/cos θ|,
where ‘n₂’ is a second refractive index of the first layer, ‘n₁’ is a first refractive index of the second layer, ‘h’ is a depth of the concave portion, and θ is an emission angle of each of the light of the first phase and the light of the second phase with respect to the rear surface of the first layer.

10. The optical member of claim 8, wherein the absolute value |Δ| of the phase difference between the light of the first phase and the light of the second phase in the first layer and the second layer satisfies |Δ|=|Δᵣ₁−Δᵣ₂|,
where Δr₁ is the first phase of light passing through the plurality of convex portions, and Δr₂ is the second phase of light passing through the plurality of concave portions.

11. The optical member of claim 10, wherein the first phase Δr₁ is provided to satisfy Δᵣ₁=n₂t/cos θ,
where ‘n₂’ is a second refractive index of the first layer, ‘t’ is a height of the convex portion from a rear surface of the first layer, and θ is an emission angle of each of the light of the first phase and the light of the second phase with respect to the rear surface of the first layer.

12. The optical member of claim 10, wherein the second phase Δr2 is provided to satisfy Δᵣ₂=n₁h/cos θ+n₂(t−h)/cos θ,
where ‘n₁’ is a first refractive index of the second layer, ‘h’ is a depth of the concave portion, ‘n₂’ is a second refractive index of the first layer, ‘t’ is a height of the convex portion from the rear surface of the first layer, and θ is an emission angle of each of the light of the first phase and the light of the second phase with respect to the rear surface of the first layer.

13. The optical member of claim 1, wherein the pattern portion is provided as any one of a curved pattern, a wave pattern, a triangular wave pattern, a zigzag pattern, and a lens-shaped pattern.

14. A display apparatus comprising:
a display panel displaying an image; and
an optical panel coupled to the display panel,
wherein the optical panel includes an optical member including:
a first layer including a top surface and a bottom surface opposite the top surface, a pattern portion formed at the top surface of the first layer, the pattern portion having a plurality of high points and a plurality of low points; and
a second layer on the first layer, the second layer on the top surface of the pattern portion of the first layer,
wherein the first layer and the second layer have their respective refractive indexes different from each other,
wherein the second layer including a plurality of middle points in the middle of adjacent high points of the plurality of high points, and
wherein, in operation, a first phase of light passing through the high points is different from a second phase of light passing through the plurality of middle points.

15. The display apparatus of claim 14, wherein the optical panel is coupled to an upper side of the display panel or a lower side of the display panel or the inside of the display panel.

16. The display apparatus of claim 14, wherein the display panel includes:
a substrate having a plurality of pixels having a plurality of subpixels; and
a light extraction portion disposed on the substrate and in each of the plurality of subpixels, and
wherein the light extraction portion overlaps at least one of the plurality of high points and the plurality of low points.

17. The display apparatus of claim 14, wherein the optical member converts external light incident from the outside toward the light extraction portion into diffractive light.

18. The display apparatus of claim 16, wherein the display panel includes:
a light emitting element layer on the light extraction portion;
an opposing substrate on the light emitting element layer to face the substrate; and
a color filter layer for color-converting light emitted from the light emitting element layer, and
wherein the color filter layer is between the light emitting element layer and the optical member.

19. The display apparatus of claim 16, wherein the light extraction portion includes a plurality of concave patterns and a plurality of convex patterns between the concave patterns, and
a pitch of the plurality of convex patterns is smaller than a pitch between adjacent high points of the plurality of high points.

20. The display apparatus of claim 16, wherein the light extraction portion includes a plurality of concave patterns and a plurality of convex patterns between the concave patterns, and
wherein one of the plurality of concave portions overlaps some of the plurality of convex patterns.

21. The display apparatus of claim 16, wherein the light extraction portion includes a plurality of concave patterns and a plurality of convex patterns between the concave patterns, and
wherein a pitch of the plurality of convex patterns is greater than a pitch between adjacent high points of the plurality of high points.

22. The display apparatus of claim 16, wherein the optical panel further includes:
a phase delay layer on the second layer;
a first protective layer on the phase delay layer;
a polarization conversion layer on the first protective layer;
a second protective layer on the polarization conversion layer;
an anti-reflective film on the second protective layer, and
an adhesive layer between the opposing substrate and the first layer.

23. The display apparatus of claim 16, wherein the optical panel further includes:
a phase delay layer below the first layer;
a polarization conversion layer on the second layer;
a protective layer on the polarization conversion layer; and
an anti-reflective film on the protective layer, and
an adhesive layer between the opposing substrate and the phase delay layer.

24. The display apparatus of claim 16, wherein the optical panel further includes:
an anti-reflective film on the second layer;
a polarization conversion layer below the first layer;
a protective layer below the polarization conversion layer; and
a phase delay layer below the protective layer, and
an adhesive layer between the opposing substrate and the phase delay layer.

25. A display apparatus comprising:
a display panel displaying an image; and
an optical panel on and coupled to the display panel,
wherein the optical panel includes an optical member including:
a first layer having a pattern portion, the pattern portion having a top surface, the pattern portion having a first high point and a second high point that are adjacent to each other; and
a second layer on the first layer, the second layer disposed along the top surface of the pattern portion of the first layer;
wherein the first layer and the second layer have their respective refractive indexes different from each other,
wherein the top surface of the pattern portion has a selected curvature between the first high point and the second high point,
wherein a third point is located between the first high point and the second high point,
wherein, in operation, external light is received through the optical panel and into the optical member, and
wherein a first phase of the external light passing through the first high point is different from a second phase of the external light passing through the third point.

26. The display apparatus of claim 25, comprising:
a phase delay layer adjacent to the optical member,
wherein the phase delay layer, in operation, delays a phase of the external light by a selected amount.

27. The display apparatus of claim 26, wherein the optical member is between the phase delay layer and the display panel.

28. The display apparatus of claim 27, wherein the second layer of the optical member is in contact with the phase delay layer.

29. The display apparatus of claim 27, wherein the second layer of the optical member is spaced apart from the phase delay layer.

30. The display apparatus of claim 26, wherein the phase delay layer is between the optical member and the display panel.

31. The display apparatus of claim 30, wherein the first layer of the optical member is in contact with the phase delay layer.

32. The display apparatus of claim 30, wherein the first layer of the optical member is spaced apart from the phase delay layer.
